(19) United States
(12) Patent Application Publication
(10) Pub. No.: US 2026/0164826 A1
(43) Pub. Date: Jun. 11, 2026

(54) IMAGE SENSOR

(71) Applicant: Samsung Electronics Co., Ltd., Suwon-si (KR)

(72) Inventors: Inyong Park, Suwon-si (KR); Nosan Park, Suwon-si (KR); Beomsuk Lee, Suwon-si (KR); Jinhyung Kim, Suwon-si (KR)

(21) Appl. No.: 19/248,968

(22) Filed: Jun. 25, 2025

(30) Foreign Application Priority Data
Dec. 10, 2024 (KR) 10-2024-0182569

(51) Int. Cl. H10F 39/00; H10F 39/18

(52) U.S. Cl. CPC H10F 39/806; H10F 39/182

(57) ABSTRACT

An image sensor includes a substrate; a first photodiode and a second photodiode both disposed in the substrate and spaced apart from each other in a first direction; a first color filter disposed on the first photodiode and a second color filter disposed on the second photodiode; and an optical structure disposed on the first and second color filters, wherein, at a predetermined height, a first distance from a center line to a sidewall of the first color filter in the first direction is greater than a second distance from the center line to a sidewall of the second color filter in the first direction, and wherein the center line extends in a second direction, and the center line is equidistant from a geometric center of the first color filter and a geometric center of the second color filter.

### CROSS-REFERENCE TO RELATED APPLICATION

This application claims priority under 35 USC § 119 to Korean Patent Application No. 10-2024-0182569, filed on Dec. 10, 2024, in the Korean Intellectual Property Office (KIPO), the contents of which are herein incorporated by reference in their entirety.

### TECHNICAL FIELD

Example embodiments relate to an image sensor.

### DISCUSSION OF RELATED ART

Image sensor resolution increases as the number of pixels grows, which may lead to increased interference (crosstalk) between color filters.

### SUMMARY

Example embodiments provide an image sensor having improved characteristics.

According to example embodiments, there is provided an image sensor. The image sensor may include a substrate, a first photodiode and a second photodiode, the first and second photodiodes both disposed in the substrate and spaced apart from each other in a first direction parallel to an upper surface of the substrate; a first color filter disposed on the first photodiode and a second color filter disposed on the second photodiode, the first and second photodiodes spaced apart from each other in the first direction; and an optical structure disposed on the first and second color filters, wherein, at a predetermined height, a first distance in the first direction from a center line between the first color filter and the second color filter to a sidewall of the first color filter facing the color filter is greater than a second distance in the first direction from a sidewall of the second color filter facing the center line to the center line, and wherein the center line extends in a second direction parallel to the upper surface of the substrate and crossing the first direction, and the center line is equidistant from a geometric center of the first color filter and a geometric center of the second color filter.

According to example embodiments, there is provided an image sensor. The image sensor may include a substrate, a first color filter group including first color filters among color filters that are disposed on the substrate and spaced apart from each other in a first direction and a second direction, the first direction parallel to an upper surface of the substrate and the second direction parallel to the upper surface of the substrate and crossing the first direction, the first color filters being adjacent to each other in the first and second directions, a second color filter group including second color filters among the color filters, the second color filters being adjacent to each other in the first and second directions, and the second color filter group being spaced apart from the first color filter group in the first direction, wherein the first color filter group defines a first air grid including first inner extension portions and second inner extension portions, wherein the first inner extension portions extend in the first direction between the first color filters adjacent to each other in the second direction, the first inner extension portions are spaced apart from each other in the second direction, the second inner extension portions extend in the second direction between the first color filters adjacent to each other in the first direction, and the second inner extension portions are spaced apart from each other in the first direction, wherein the second color filter group defines a second air grid including third inner extension portions and fourth inner extension portions, wherein the third inner extension portions extend in the first direction between the second color filters adjacent to each other in the second direction, the third inner extension portions are spaced apart from each other in the second direction, the fourth inner extension portions extend in the second direction between the second color filters adjacent to each other in the first direction, and the fourth inner extension portions are spaced apart from each other in the first direction, wherein, at a predetermined height, each of the first inner extension portions has a first width between opposing side surfaces of first color filters defining the first inner extension portion in the second direction, each of the third inner extension portions has a second width between opposing side surfaces of second color filters defining the third extension portions in the second direction, and the first width is greater than the second width.

According to example embodiments, there is provided an image sensor. The image sensor may include a substrate, photodiodes in the substrate and spaced apart from each other in a first direction and a second direction, the first direction parallel to an upper surface of the substrate and the second direction parallel to the upper surface of the substrate and crossing the first direction, color filters spaced apart from each other in the first and second directions and respectively disposed on the photodiodes, the color filters defining an air grid between adjacent color filters, the air grid including first extension portions and second extension portions, wherein the first extension portions extend in the first direction between the color filters adjacent to each other in the second direction, the first extension portions are spaced apart from each other in the second direction, the second extension portions extend in the second direction between the color filters adjacent to each other in the first direction, and the second extension portions are spaced apart from each other in the first direction; a capping layer disposed on the color filters and over the air grid; and an optical structure disposed on the capping layer, wherein each of first color filters among the color filters has a first volume, each of second color filters among the color filters has a second volume, and the first volume is smaller than the second volume.

According to example embodiments, there is provided a method of manufacturing an image sensor. The method of manufacturing an image sensor may include forming photodiodes in a substrate that are spaced apart from each other in a first direction parallel to an upper surface of the substrate; forming a first preliminary color filter and a second preliminary color filter adjacent to each other in the first direction on the photodiodes, respectively; performing a patterning process on the first and second preliminary color filters to form a first color filter having a width reduced by a first width in the first direction compared to the first preliminary color filter and a second color filter having a width reduced by a second width in the first direction compared to the second preliminary color filter, wherein a first space extending in a second direction parallel to the upper surface of the substrate and crossing the first direction is formed between the first and second color filters; forming a capping layer on the first and second color filters to close an upper end of the first space thereby defining an air grid; and forming an optical structure on the capping layer, wherein the first width is greater than the second width.

According to example embodiments of a method manufacturing an image sensor, the first color filter is a green color filter, and the second color filter is a blue color filter or a red color filter.

According to example embodiments of a method manufacturing an image sensor, the first and second preliminary color filters are in contact with each other.

According to example embodiments of a method manufacturing an image sensor, the first color filter has a third width in the first direction, the second color filter has a fourth width in the first direction, and the third width is smaller than the fourth width.

According to example embodiments of a method manufacturing an image sensor, the first color filter has a first height in a vertical direction perpendicular to the upper surface of the substrate, the second color filter has a second height in the vertical direction, and the first height is smaller than the second height.

According to example embodiments of a method manufacturing an image sensor, the first color filter has a first volume, the second color filter has a second volume, and the first volume is smaller than the second volume.

An image sensor according to example embodiments may include an air grid that prevents interference between adjacent color filters. Since the air grid may include air, which has a relatively low refractive index, interference between the adjacent color filters may be minimized.

Additionally, by adjusting a width of an air grid, sensitivity for each of the color filters according to its color and sensitivity ratio between the color filters may be controlled.

### BRIEF DESCRIPTION OF THE DRAWINGS

FIGS. 1 and 2 are a horizontal cross-sectional view and a vertical cross-sectional view illustrating an arrangement of color filters of an image sensor in accordance with example embodiments.

FIGS. 3 to 6 are cross-sectional views illustrating a method of forming an image sensor in accordance with example embodiments.

FIGS. 7 to 17 are horizontal cross-sectional views illustrating an arrangement of color filters of an image sensor in accordance with example embodiments.

FIGS. 18 and 19 are vertical cross-sectional views illustrating an image sensor in accordance with example embodiments.

FIG. 20 is a plan view illustrating an image sensor in accordance with example embodiments.

FIG. 21 is a cross-sectional view illustrating an image sensor in accordance with example embodiments.

FIGS. 22 to 28 are cross-sectional views illustrating a method of forming an image sensor in accordance with example embodiments.

FIG. 29 is a cross-sectional view illustrating an image sensor in accordance with example embodiments.

FIGS. 30 to 33 are cross-sectional views illustrating a method of forming an image sensor in accordance with example embodiments.

### DESCRIPTION OF EMBODIMENTS

Image sensors and methods of manufacturing the image sensors in accordance with example embodiments will be described more with reference to the accompanying drawings, in which various embodiments are shown. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

Throughout the specification, when a component is described as “including” a particular element or group of elements, it is to be understood that the component may be formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

In the following description should be appreciated that an “air grid” is grid defined by an absence of solid material between adjacent objects that define the boundaries of the air grid. The absence of material between the adjacent objects may form an “air gap” which may comprise a gap having air or other gases (e.g., such as those present during manufacturing) therein or may comprise a gap forming a vacuum therein.

The term “air” as discussed herein, may refer to atmospheric air, or other gases that may be present during the manufacturing process.

It will be understood that, although the terms “first,” “second,” and/or “third” may be used herein to label various elements, components, regions, layers and/or sections, these labels of the elements, components, regions, layers, and/or sections should not be limited by these labels. These labels are only used to distinguish one element, component, region, layer or section from another region, layer, or section. Thus, a first element, component, region, layer, or section discussed below could be labeled a second or third element, component, region, layer, or section in another portion of the description or the claims without departing from the teachings of inventive concepts.

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

A direction parallel to a surface of a substrate 10, such as an upper or lower surface, may be referred to as a horizontal direction, and a direction perpendicular to the surface of the substrate 10 may be referred to as a vertical direction. The horizontal direction may include first and second directions D1 and D2, which may be perpendicular to each other, and the vertical direction may include a third direction D3.

In the specifications, terms such as up vs. down, on and over vs. beneath and under, upper surface vs. lower surface, and upper portion vs. lower portion are relative and describe opposite sides in a vertical direction, and the terms of identified pair may have opposite meanings according to the specific parts to be explained in the specifications.

In some cases, a region defined in the substrate may include not only a portion of the substrate but also a space over and/or under the substrate that may overlap the region in the vertical direction.

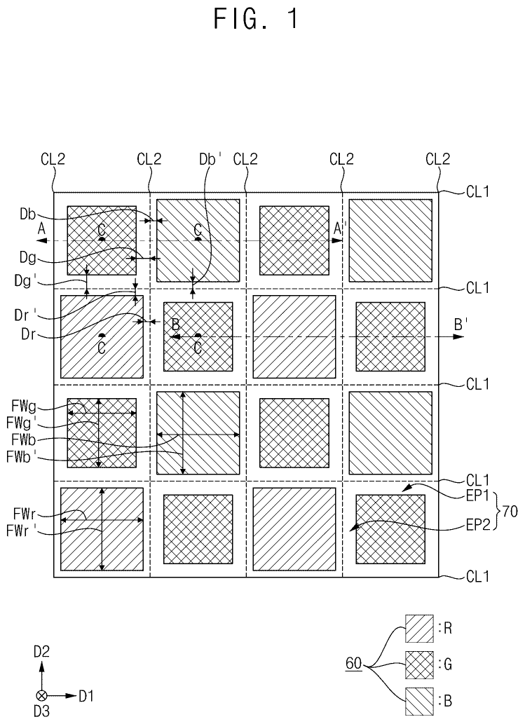

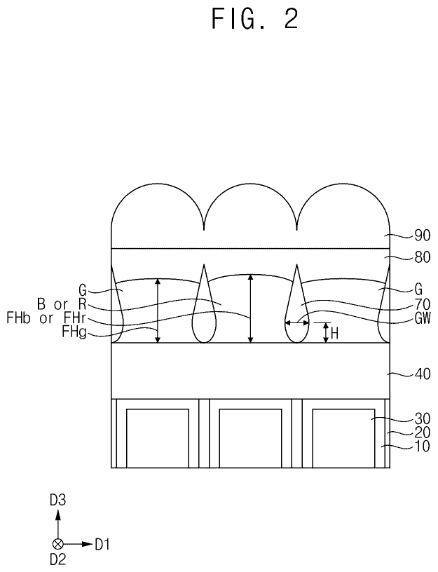

FIG. 1 is a horizontal cross-sectional view of an image sensor according to some embodiments at a predetermined height H of FIG. 2, and FIG. 2 is a vertical cross-sectional view of an image sensor according to some embodiments. FIGS. 1 and 2 illustrate an arrangement of color filters of an image sensor in accordance with example embodiments. FIG. 2 is a cross-sectional view taken along line A-A′ or B-B′ of FIG. 1.

Referring to FIGS. 1 and 2, pixels of the image sensor may include a pixel division pattern 20, light sensing elements 30 respectively disposed in unit pixel regions defined by the pixel division pattern 20, a planarization layer 40, color filters 60, an air grid 70, a capping layer 80, and an optical structure 90.

A transparent electrode layer may be further disposed on the optical structure 90.

In example embodiments, a substrate 10 may include silicon, germanium, silicon-germanium, or a III-V group compound semiconductor, such as GaP, GaAs, or GaSb. In example embodiments, p-type wells doped with p-type impurities, e.g., boron, aluminum, gallium, etc., may be provided partially or entirely within the substrate 10.

In example embodiments, the pixel division pattern 20 may extend through the substrate 10 in the third direction D3. In example embodiments, in a plan view, the pixel division pattern 20 may have, for example, a grid shape. The unit pixel regions, in which unit pixels are respectively disposed, may be defined by the pixel division pattern 20. In example embodiments, the unit pixel regions may be arranged along first and second directions D1 and D2. The unit pixel regions may include not only portions of the substrate 10 but also spaces over and/or under the substrate 10 that may overlap the portions of the substrate 10 in the third direction D3.

In example embodiments, the pixel division pattern 20 may include an insulating material, for example, an oxide or nitride, or a semiconductor material, for example, polysilicon. Alternatively, the pixel division pattern 20 may include a conductive material such as doped polysilicon, a metal, or a metal nitride.

In example embodiments, the light sensing elements 30 may be photodiodes PD. For example, the light sensing elements 30 may be regions doped with n-type impurities within the p-type wells provided in the substrate 10.

In example embodiments, the light sensing elements 30 may be respectively provided in the unit pixel regions of the substrate 10 defined by the pixel division pattern 20. In FIGS. 1 and 2, one of the light sensing elements 30 may be disposed in each of the unit pixel regions, but the concept of the present invention is not limited thereto. For example, two or more of the light sensing elements 30 may be arranged in each of the unit pixel regions.

The planarization layer 40 may be disposed on the upper surface of the substrate 10 and may have a single layer structure or a composite layer structure sequentially stacked along a vertical direction substantially perpendicular to the upper surface of the substrate 10. In example embodiments, the planarization layer 40 may include first to fifth layers sequentially stacked, which may include, for example, aluminum oxide, hafnium oxide, silicon oxide, silicon nitride, and hafnium oxide, respectively.

The color filters 60 may be disposed on the planarization layer 40 and may be spaced apart from each other in the first and second directions D1 and D2 by the air grid 70 which may correspond to the pixel division pattern 20 in the third direction D3. Some of the color filters 60 may be first color filters G, others of the color filters 60 may be second color filters B, and still others of the color filters 60 may be third color filters R. The first to third color filters G, B and R may be green color filters, blue color filters, and red color filters, respectively.

The first to third color filters G, B and R may be arranged in a Bayer pattern, but the concept of the present invention is not limited thereto. For example, the first to third color filters G, B and R may have other extended arrangement structures such as a Quad Bayer pattern, a Tetra-cell layout, a Nona-cell layout, a Tetra² layout, etc.

In example embodiments, each of the first to third color filters G, B and R may have a square shape in a plan view.

Each of the first color filters G may have a first filter width FWg in the first direction D1, each of the second color filters B may have a second filter width FWb in the first direction D1, and each of the third color filters R may have a third filter width FWr in the first direction D1. In example embodiments, the first filter width FWg may be smaller than the second filter width FWb. In example embodiments, the first filter width FWg may be smaller than the third filter width FWr.

Each of the first color filters G may have a first filter width′ FWg′ in the second direction D2, each of the second color filters B may have a second filter width′ FWb′ in the second direction D2, and each of the third color filters R may have a third filter width′ FWr′ in the second direction D2. In example embodiments, the first filter width′ FWg′ may be smaller than the second filter width′ FWb′. In example embodiments, the first filter width′ FWg′ may be smaller than the third filter width′ FWr′.

In example embodiments, the first filter width FWg, the second filter width FWb, and the third filter width FWr may be substantially the same as the first filter width′ FWg′, the second filter width′ FWb′, and the third filter width′ FWr′, respectively. For example, the first to third color filters G, B and R may have a square shape in a plan view.

Each of the first color filters G may have a first filter height FHg in the third direction D3, each of the second color filters B may have a second filter height FHb in the third direction D3, and each of the third color filters R may have a third filter height FHr in the third direction D3. In example embodiments, the first filter height FHg may be smaller than the second filter height FHb. In example embodiments, the first filter height FHg may be smaller than the third filter height FHr. A filter height may the maximum distance between a lower surface of a color filter and the upper surface of the color filter in a vertical direction.

Each of the first color filters G may have a first volume, each of the second color filters B may have a second volume, and each of the third color filters R may have a third volume. In example embodiments, the first volume may be smaller than the second volume. In example embodiments, the first volume may be smaller than the third volume.

The air grid 70 may have a grid shape in a plan view, corresponding to the pixel division pattern 20.

In example embodiments, the air grid 70 may include first extension portions EP1 and second extension portions EP2. The first extension portions EP1 of the air grid 70 may extend in the first direction D1 along first center lines CL1 and may be spaced apart from each other in the second direction D2. The second extension portions EP2 of the air grid 70 may extend in the second direction D2 along second center lines CL2 and may be spaced apart from each other in the first direction D1. A first center line CL1 may be a first reference line parallel to the upper surface of the substrate in which every point on the line is equidistant in the second direction D2 from geometric centers C (e.g., a center of gravity) of the color filters 60 adjacent to the first center line CL1 in the second direction D2, and a second center line CL2 may be a second reference line parallel to the upper surface of the substrate in which every point on the line is equidistant in the first direction D1 from geometric centers C (e.g., a center of gravity) of the color filters 60 adjacent to the second center line CL2 in the first direction D1.

In example embodiments, the first extension portions EP1 and the second extension portions EP2 of the air grid 70 may overlap (e.g., intersect) each other at intersections of the first and second center lines CL1 and CL2.

In example embodiments, the first extension portions EP1 and the second extension portions EP2 of the air grid 70 may collectively form a single space.

In example embodiments, the air grid 70 may be defined as a space surrounded by an upper surface of the planarization layer 40, sidewalls of the color filters 60 in the first and second directions D1 and D2, and a lower surface of the capping layer 80. For example, an upper surface of the planarization layer 40, sidewalls of the color filters 60 in the first and second directions D1 and D2, and a lower surface of the capping layer 80 may define the air grid 70.

At the predetermined height H, the second center line CL2 and a sidewall facing the second center line CL2 of a first color filter G adjacent to the second center line CL2 in the first direction D1 may have a first distance Dg therebetween in the first direction D1. At the predetermined height H, the second center line CL2 and a sidewall facing the second center line CL2 in the first direction D1 of a second color filter B adjacent to the second center line CL2 in the first direction D1 may have a second distance Db therebetween in the first direction D1. At the predetermined height H, the second center line CL2 and a sidewall facing the second center line CL2 in the first direction D1 of a third color filter R adjacent to the second center line CL2 in the first direction D1 may have a third distance Dr therebetween in the first direction D1. In example embodiments, the first distance Dg may be greater than the second distance Db. In example embodiments, the first distance Dg may be greater than the third distance Dr.

At the predetermined height H, the first center line CL1 and a sidewall facing the first center line CL1 in the second direction D2 of a first color filter G adjacent to the first center line CL1 in the second direction D2 may have a first distance′ Dg′ therebetween in the second direction D2. At the predetermined height H, the first center line CL1 and a sidewall facing the first center line CL1 in the second direction D2 of a second color filter B adjacent to the first center line CL1 in the second direction D2 may have a second distance′ Db′ therebetween in the second direction D2. At the predetermined height H, the first center line CL1 and a sidewall facing the first center line CL1 in the second direction D2 of a third color filter R adjacent to the first center line CL1 in the second direction D2 may have a third distance′ Dr′ therebetween in the second direction D2. In example embodiments, the first distance′ Dg′ may be greater than the second distance′ Db′. In example embodiments, the first distance′ Dg′ may be greater than the third distance′ Dr′.

In example embodiments, the first distance Dg, the second distance Db, and the third distance Dr may be substantially the same as the first distance′ Dg′, the second distance′ Db′, and the third distance′ Dr′, respectively.

In example embodiments, a grid width GW of each of the first extension portions EP1 or each of the second extension portions EP2 of the air grid 70 in a vertical cross-section may increase and then decrease as the distance in the third direction D3 from the upper surface of the planarization layer 40 increases.

In example embodiments, an upper portion of the vertical cross-section of each of the first extension portions EP1 or each of the second extension portions EP2 of the air grid 70 may include a pointed tip as shown in FIG. 2.

The air grid 70 serves as a barrier between adjacent pixels by preventing light entering one pixel from entering neighboring pixels and thus preventing optical interference. The air grid 70 may include air or may include another gas.

The capping layer 80 may be disposed on the color filters 60 and may form an upper end of the air grid 70. The capping layer 80 may include a material with a low step coverage characteristic. The capping layer 80 may include an oxide, for example, silicon oxide, a nitride, for example, silicon nitride, an organic insulating material, etc. In example embodiments, the capping layer 80 may have a composite layer structure.

The optical structure 90 may be disposed on the capping layer 80 and may serve to gather light incident on the pixels. The optical structure 90 of the figures are shown to be a micro lens, but the concept of the present invention is not limited thereto. For example, the optical structure 90 may also be a Nano Prism, a Meta Micro Lens, etc.

In the image sensor, the first distance Dg may be greater than the second distance Db and/or the third distance Dr, and thus, the first volume of the first color filter G may be smaller than the second volume of the second color filter B and/or the third volume of the third color filter R. Accordingly, sensitivity to green, to which the human eye is most sensitive, may be increased in the image sensor.

Additionally, by adjusting a ratio between the first to third distances Dg, Db and Dr and/or the first to third distances′ Dg′, Db′ and Dr′, a volume ratio between the first to third color filters G, B and R may be adjusted. Accordingly, sensitivity of the image sensor for each color (for example, green, blue, and/or red) and sensitivity ratio between the colors may be optimized.

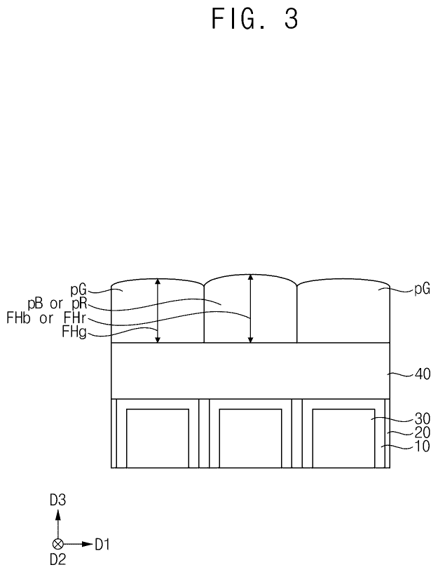

FIGS. 3 to 6 are cross-sectional views illustrating a method of forming an image sensor in accordance with example embodiments.

Referring to FIG. 3, preliminary color filters p60 may be formed on a planarization layer 40. In example embodiments, the preliminary color filters p60 adjacent to each other in the first direction D1 or the second direction D2 may be formed to contact each other.

Some of the preliminary color filters p60 may be first preliminary color filters pG, others of the preliminary color filters p60 may be second preliminary color filters pB, and still others of the preliminary color filters p60 may be third preliminary color filters pR. The first to third preliminary color filters pG, pB and pR may be green preliminary color filters, blue preliminary color filters, and red preliminary color filters, respectively.

Each of the first preliminary color filters pG may be formed to have a first filter height FHg in the third direction D3, each of the second preliminary color filters pB may be formed to have a second filter height FHb in the third direction D3, and each of the third preliminary color filters pR may be formed to have a third filter height FHr in the third direction D3. In example embodiments, the first filter height FHg may be formed to be smaller than the second filter height FHb. In example embodiments, the first filter height FHg may be formed to be smaller than the third filter height FHr.

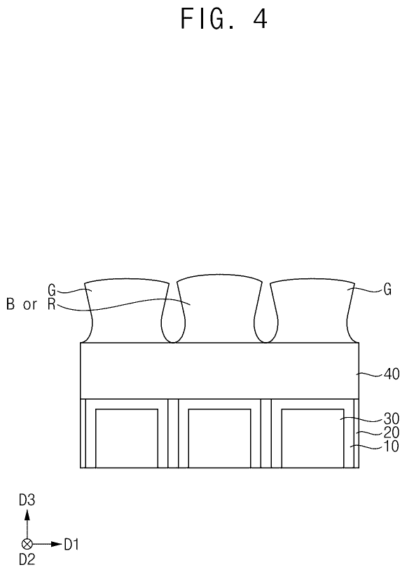

Referring to FIG. 4, a patterning process may be performed on the preliminary color filters p60. Accordingly, the preliminary color filters p60 may be respectively transformed into color filters 60 spaced apart from each other in the first and second directions D1 and D2. Also, the first to third preliminary color filters pG, pB and pR may be transformed into first to third color filters G, B and R, respectively.

By the patterning process, first spaces extending in the first direction D1 may be formed between the preliminary color filters p60 adjacent to each other in the second direction D2, and second spaces extending in the second direction D2 may be formed between the color filters 60 adjacent to each other in the first direction D1.

During the patterning process, a width in the first direction D1 of each of the first preliminary color filters pG may be reduced by a first width in the first direction D1 at an arbitrary height H, a width in the first direction D1 of each of the second preliminary color filters pB may be reduced by a second width in the first direction D1 at the arbitrary height H, and a width in the first direction D1 of each of the third preliminary color filters pR may be reduced by a third width in the first direction D1 at the arbitrary height H. In example embodiments, the first width may be greater than the second width. In example embodiments, the first width may be greater than the third width.

Also, during the patterning process, a width in the second direction D2 of each of the first preliminary color filters pG may be reduced by a first width′ in the second direction D2 at the arbitrary height H, a width in the second direction D2 of each of the second preliminary color filters pB may be reduced by a second width′ in the second direction D2 at the arbitrary height H, and a width in the second direction D2 of each of the third preliminary color filters pR may be reduced by a third width′ in the second direction D2 at the arbitrary height H. In example embodiments, the first width′ may be greater than the second width′. In example embodiments, the first width′ may be greater than the third width′.

In example embodiments, the first to third widths may be substantially the same as the first to third widths′, respectively.

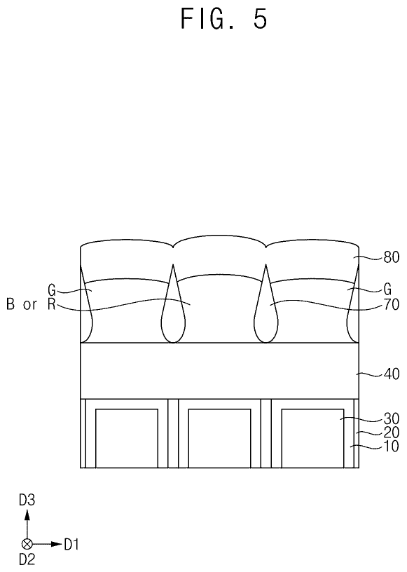

Referring to FIG. 5, a capping layer 80 may be formed on the color filters 60. The capping layer 80 includes a material with a low step coverage characteristic, and thus, upper ends of the first and second spaces may be closed by the capping layer 80. Accordingly, the first and second spaces may collectively form an air grid 70.

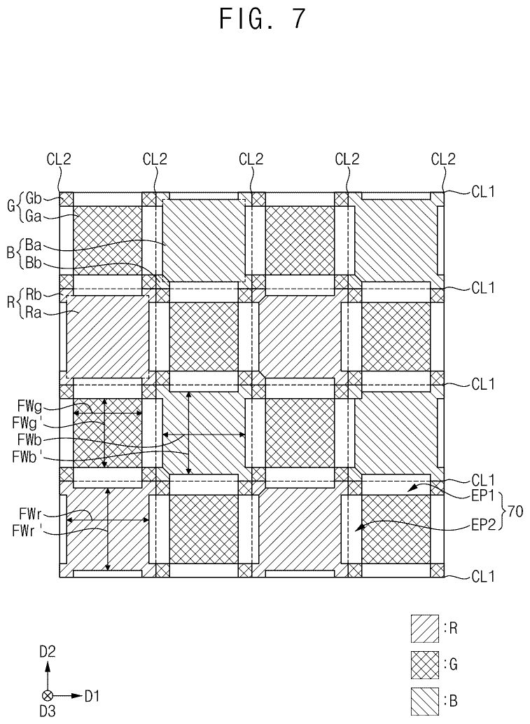

In example embodiments, an upper portion of a vertical cross-section of the air grid 70 may be formed to have a pointed tip as shown in FIG. 7.

In example embodiments, an upper surface of the capping layer 80 may be formed to have a varying height with respect to the upper surface of the substrate 10, corresponding to upper surfaces of the first to third color filters G, B and R (e.g., the shape of the upper surface may correspond to the shape of the upper surfaces of the first to third color filters G, B, and R).

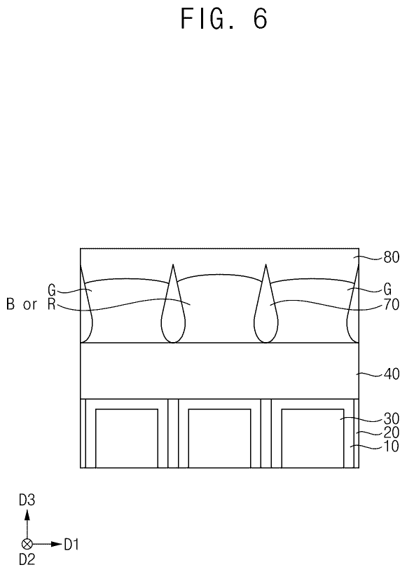

Referring to FIG. 6, a planarization process may be performed on an upper portion of the capping layer 80. Accordingly, the upper surface of the capping layer 80 may be formed to have a constant height with respect to the upper surface of the substrate 10.

The planarization process may be performed by, for example, a chemical mechanical polishing (CMP) process and/or an etch-back process.

Referring again to FIGS. 1 and 2, an optical structure 90 may be formed on the capping layer 80.

In the method of manufacturing the image sensor, by adjusting the width in the horizontal direction of material to be removed in each of the first to third color filters G, B and R during the patterning process, the volume of the first to third color filters G, B and R may be adjusted, thereby optimizing the sensitivity of the image sensor for each color and the sensitivity ratio between colors.

FIG. 7 is a cross-sectional view illustrating an image sensor according to example embodiments, corresponding to FIG. 1. The image sensor may be substantially the same or similar to those described with reference to FIGS. 1 and 2 except for the shape of the color filters 60 and the shape of the air grid 70, and thus, repeated descriptions of previously described elements may be omitted herein.

Referring to FIG. 7, each of the first color filters G may include a first central portion Ga and first corner portions Gb. In example embodiments, the first central portion Ga may have a square shape in a plan view. In example embodiments, each of the first corner portions Gb may have a square shape in a plan view. In example embodiments, each of the first corner portions Gb may have an ‘L’ shape or a shape in which the ‘L’ shape is rotated by 90 degrees, 180 degrees, or 270 degrees clockwise in a plan view. In example embodiments, the first corner portions Gb may be respectively disposed at vertices of the first central portion Ga.

Each of the second color filters B may include a second central portion Ba and second corner portions Bb. In example embodiments, the second central portion Ba may have a square shape in a plan view. In example embodiments, each of the second corner portions Bb may have a square shape in a plan view. In example embodiments, each of the second corner portions Bb may have an ‘L’ shape or a shape in which the ‘L’ shape is rotated by 90 degrees, 180 degrees, or 270 degrees clockwise in a plan view. In example embodiments, the second corner portions Bb may be respectively disposed at vertices of the second central portion Ba.

Each of the third color filters R may include a third central portion Ra and third corner portions Rb. In example embodiments, the third central portion Ra may have a square shape in a plan view. In example embodiments, each of the third corner portions Rb may have a square shape in a plan view. In example embodiments, each of the third corner portions Rb may have an ‘L’ shape or a shape in which the ‘L’ shape is rotated by 90 degrees, 180 degrees, or 270 degrees clockwise in a plan view. In example embodiments, the third corner portions Rb may be respectively disposed at vertices of the third central portion Ra.

Each of the first central portions Ga of the first color filters G may have a first filter width FWg in the first direction D1, each of the second central portions Ba of the second color filters B may have a second filter width FWb in the first direction D1, and each of the third central portions Ra of the third color filters R may have a third filter width FWr in the first direction D1. In example embodiments, the first filter width FWg may be smaller than the second filter width FWb. In example embodiments, the first filter width FWg may be smaller than the third filter width FWr.

Each of the first central portions Ga of the first color filters G may have a first filter width′ FWg′ in the second direction D2, each of the second central portions Ba of the second color filters B may have a second filter width′ FWb′ in the second direction D2, and each of the third central portions Ra of the third color filters R may have a third filter width′ FWr′ in the second direction D2. In example embodiments, the first filter width′ FWg′ may be smaller than the second filter width′ FWb′. In example embodiments, the first filter width′ FWg′ may be smaller than the third filter width′ FWr′.

In example embodiments, the first filter width FWg, the second filter width FWb, and the third filter width FWr may be substantially the same as the first filter width′ FWg′, the second filter width′ FWb′, and the third filter width′ FWr′, respectively. For example, the first to third color filters G, B, R may have a square shape in a plan view.

In example embodiments, the first corner portions Gb of the first color filter G and the second corner portions Bb of the second color filter B adjacent to each other in the first direction D1 may contact each other. In example embodiments, the first corner portions Gb of the first color filter G and the third corner portions Rb of the third color filter R adjacent to each other in the first direction D1 may contact each other.

In example embodiments, the first corner portions Gb of the first color filter G and the second corner portions Bb of the second color filter B adjacent to each other in the second direction D2 may contact each other. In example embodiments, the first corner portions Gb of the first color filter G and the third corner portions Rb of the third color filter R adjacent to each other in the second direction D2 may contact each other.

In example embodiments, a sidewall in the first direction D1 of a first corner portion Gb of the first color filter G may contact a sidewall in the first direction D1 of a second corner portion Bb of the second color filter B, and a sidewall in the second direction D2 of the first corner portion Gb of the first color filter G may contact a sidewall in the second direction D2 of the third corner portion Rb of the third color filter R. Alternatively, the sidewall in the second direction D2 of the first corner portion Gb of the first color filter G may contact a sidewall in the second direction D2 of the second corner portion Bb of the second color filter B, and the sidewall in the first direction D1 of the first corner portion Gb of the first color filter G may contact a sidewall in the first direction D1 of the third corner portion Rb of the third color filter R.

In example embodiments, unlike the image sensor described with reference to FIGS. 1 and 2, the first extension portions EP1 and the second extension portions EP2 of the air grid 70 may not overlap each other (e.g., may be spaced apart or not intersect). For example, each of the first extension portions EP1 of the air grid 70 may be separated at the intersections of the first and second center lines CL1 and CL2 into a plurality of first extension sub portions spaced apart from each other in the first direction D1. For example, each of the second extension portions EP2 of the air grid 70 may be separated at the intersections of the first and second center lines CL1 and CL2 into a plurality of second extension sub portions spaced apart from each other in the second direction D2.

In example embodiments, each of the first extension portions EP1 of the air grid 70 may be a space defined by the upper surface of the planarization layer 40, a sidewall in the second direction D2 of the first central portion Ga of the first color filter G and a sidewall in the second direction D2 of the second central portion Ba of the second color filter B facing each other in the second direction D2, sidewalls in the first direction D1 of the first corner portions Gb of the first color filter G facing each other in the first direction D1, sidewalls in the first direction D1 of the second corner portions Bb of the second color filter B facing each other in the first direction D1, and the lower surface of the capping layer 80, or a space defined by the upper surface of the planarization layer 40, the sidewall in the second direction D2 of the first central portion Ga of the first color filter G and a sidewall in the second direction D2 of the third central portion Ra of the third color filter R facing each other in the second direction D2, the sidewalls G in the first direction D1of the first corner portions Gb of the first color filter facing each other in the first direction D1, sidewalls in the first direction D1 of the third corner portions Rb of the third color filter R facing each other in the first direction D1, and the lower surface of the capping layer 80.

In example embodiments, each of the second extension portions EP2 of the air grid 70 may be a space defined by the upper surface of the planarization layer 40, a sidewall in the first direction D1 of the first central portion Ga of the first color filter G and a sidewall in the first direction D1 of the second central portion Ba of the second color filter B facing each other in the first direction D1, sidewalls in the second direction D2 of the first corner portions Gb of the first color filter G facing each other in the second direction D2, sidewalls in the second direction D2 of the second corner portions Bb of the second color filter B facing each other in the second direction D2, and the lower surface of the capping layer 80, or a space defined by the upper surface of the planarization layer 40, the sidewall in the first direction D1 of the first central portion Ga of the first color filter G and a sidewall in the first direction D1 of the third central portion Ra of the third color filter R facing each other in the first direction D1, the sidewalls in the second direction D2 of the first corner portions Gb of the first color filter G facing each other in the second direction D2, sidewalls in the second direction D2 of the third corner portions Rb of the third color filter R facing each other in the second direction D2, and the lower surface of the capping layer 80.

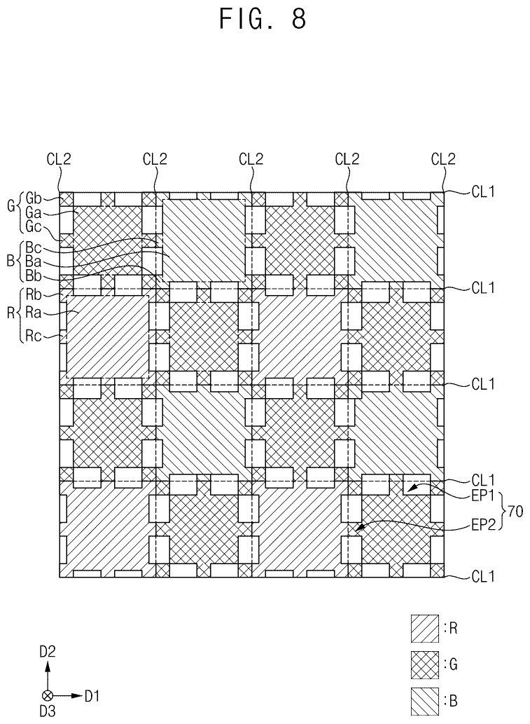

FIG. 8 is a cross-sectional view illustrating an image sensor according to example embodiments, corresponding to FIG. 7. The image sensor may be substantially the same, or similar to those described with reference to FIGS. 1 and 2 and may differ primarily in the shape of the color filters 60 and the shape of the air grid 70, and thus, repeated description of elements described previously may be omitted herein.

Referring to FIG. 8, the first color filter G may include not only the first central portion Ga and the first corner portions Gb but also a first side protrusions Gc. Only one first side protrusion Gc is shown to be disposed on each of the sidewalls in the first and second directions D1 and D2 of the first central portion Ga of the first color filter G, but the concept of the present invention is not limited thereto. For example, a plurality of first side protrusions Gc may be disposed on each of the sidewalls in the first and second directions D1 and D2 of the first central portion Ga of the first color filter G.

The second color filter B may include not only the second central portion Ba and the second corner portions Bb but also a second side protrusions Bc. Only one second side protrusion Bc is shown to be disposed on each of the sidewalls in the first and second directions D1 and D2 of the first central portion Ba of the second color filter B, but the concept of the present invention is not limited thereto. For example, a plurality of second side protrusions Bc may be disposed on each of the sidewalls in the first and second directions D1 and D2 of the second central portion Ba of the second color filter B.

The third color filters R may include not only the third central portion Ra and the third corner portions Rb but also a third side protrusions Rc. Only one third side protrusion Rc is shown to be disposed on each of the sidewalls in the first and second directions D1 and D2 of the third central portion Ra of the third color filter R, but the concept of the present invention is not limited thereto. For example, a plurality of third side protrusions Rc may be disposed on each of the sidewalls in the first and second directions D1 and D2 of the third central portion Ra of the third color filter R.

In example embodiments, each of the first side protrusions Gc may have a square shape in a plan view. In example embodiments, each of the second side protrusions Bc may have a square shape in a plan view. In example embodiments, each of the third side protrusions Rc may have a square shape in a plan view.

In example embodiments, the first side protrusions Gc of the first color filter G and the second side protrusions Bc of the second color filter B adjacent to each other in the first direction D1 may contact each other. In example embodiments, the first side protrusions Gc of the first color filter G and the third side protrusions Rc of the third color filter R adjacent to each other in the first direction D1 may contact each other. In example embodiments, the first side protrusions Gc of the first color filter G and the second side protrusions Bc of the second color filter B adjacent to each other in the second direction D2 may contact each other. In example embodiments, the first side protrusions Gc of the first color filter G and the third side protrusions Rc of the third color filter R adjacent to each other in the second direction D2 may contact each other.

In example embodiments, each of the first extension portions EP1 of the air grid 70 may be divided by the first side protrusions Gc of the first color filter G and the second side protrusions Bc of the second color filter B contacting each other or the first side protrusions Gc of the first color filter G and the third side protrusions Rc of the third color filter R contacting each other into a plurality of first extension sub portions spaced apart from each other in the first direction D1. In example embodiments, each of the second extension portions EP1 of the air grid 70 may be divided by the first side protrusions Gc of the first color filter G and the second side protrusions Bc of the second color filter B contacting each other or the first side protrusions Gc of the first color filter G and the third side protrusions Rc of the third color filter R contacting each other into a plurality of second extension sub portions spaced apart from each other in the second direction D2.

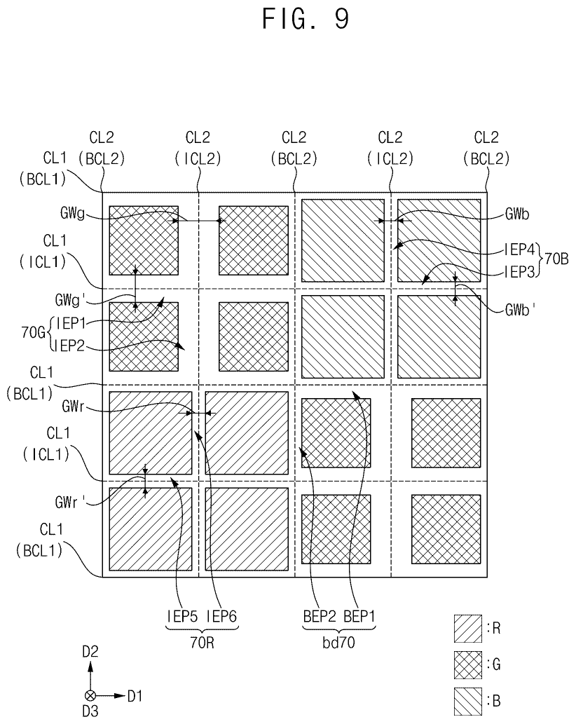

FIG. 9 is a cross-sectional view illustrating an image sensor according to example embodiments, corresponding to FIG. 1. The image sensor may be substantially the same, or similar to those described with reference to FIGS. 1 and 2 and differs primarily in the shape of the air grid 70 and the arrangement of the first to third color filters G, B and R, and thus, repeated description of elements described previously may be omitted herein.

Referring to FIG. 9, color filter groups may include a group of the color filters 60 that filter light of the same color and are adjacent to each other. For example, among the color filter groups, first color filter groups may include the first color filters G that filter green light and are adjacent to each other. For example, among the color filter groups, second color filter groups may include the second color filters B that filter blue light and are adjacent to each other. For example, among the color filter groups, third color filter groups may include the third color filters R that filter red light and are adjacent to each other.

In FIG. 9, each of the first color filter groups is shown to include four of the first color filters G arranged in 2 rows and 2 columns, each of the second color filter groups is shown to include four of the second color filters G arranged in 2 rows and 2 columns, and each of the third color filter groups is shown to include four of the third color filters R arranged in 2 rows and 2 columns, such that the first to third color filters G, B and R are arranged in a Quad Bayer pattern, but the concept of the present invention is not limited thereto. For example, the first to third color filters G, B and R may have other extended arrangement structures such as a Tetra-cell layout, a Nona-cell layout, a Tetra² layout, etc.

Hereinafter, the first extension portions EP1 of the air grid 70 that extend in the first direction D1 between the color filter groups adjacent to each other in the second direction D2 will be referred to as first boundary extension portions BEP1. The second extension portions EP2 of the air grid 70 that extend in the second direction D2 between the color filter groups adjacent to each other in the first direction D1 will be referred to as second boundary extension portions BEP2. The first and second boundary extension portions BEP1 and BEP2 may collectively form a boundary air grid bd70.

The first center lines CL1 that may overlap with the boundary air grid bd70 in the vertical direction may also be referred to as first boundary center lines BCL1. The second center lines CL2 that overlap with the boundary air grid bd70 in the vertical direction may also be referred to as second boundary center lines BCL2.

In example embodiments, the first boundary extension portions BEP1 and the second boundary extension portions BEP2 of the boundary air grid bd70 may overlap each other at intersections of the first and second boundary center lines BCL1 and BCL2.

At the predetermined height H, a second boundary center line BCL2 and a sidewall facing the second center line CL2 in the first direction D1 of a color filter 60 adjacent to the second boundary center line BCL2 in the first direction D1 may have a fourth distance therebetween in the first direction D1. At the predetermined height H, a first boundary center line BCL1 and a sidewall facing the first center line CL1 in the second direction D2 of the color filter 60 adjacent to the first boundary center line BCL1 in the second direction D2 may have a fifth distance therebetween in the second direction D2. In example embodiments, the fourth distance may be substantially the same as the fifth distance.

Hereinafter, portions of the first extension portions EP1 of the air grid 70 that extend in the first direction D1 between the first color filters G included in the first color filter groups will be referred to as first inner extension portions IEP1. Portions of the second extension portions EP2 of the air grid 70 that extend in the second direction D2 between the first color filters G included in the first color filter groups will be referred to as second inner extension portions IBP2. The first and second inner extension portions IEP1 and IEP2 may collectively form a first air grid 70G.

Portions of the first extension portions EP1 of the air grid 70 that extend in the first direction D1 between the second color filters B included in the second color filter groups will be referred to as third inner extension portions IEP3. Portions of the second extension portions EP2 of the air grid 70 that extend in the second direction D2 between the second color filters B included in the second color filter groups will be referred to as fourth inner extension portions IEP4. The third and fourth inner extension portions IEP3 and IEP4 may collectively form a second air grid 70B.

Portions of the first extension portions EP1 of the air grid 70 that extend in the first direction D1 between the third color filters R included in the third color filter groups will be referred to as fifth inner extension portions IEP5. Portions of the second extension portions EP2 of the air grid 70 that extend in the second direction D2 between the third color filters R included in the third color filter groups will be referred to as sixth inner extension portions IEP6. The fifth and sixth inner extension portions IEP5 and IEP6 may collectively form a third air grid 70R.

The first center lines CL1 that overlap with the first to third air grids 70G, 70B and 70R in the vertical direction will be referred to as first inner center lines ICL1. The second center lines CL2 that overlap with the first to third air grids 70G, 70B and 70R in the vertical direction will be referred to as second inner center lines ICL2.

In example embodiments, the first inner extension portions IEP1 and the second inner extension portions IEP2 of the first air grid 70G may overlap each other at intersections of the first and second inner center lines ICL1 and ICL2.

In example embodiments, the third inner extension portions IEP3 and the fourth inner extension portions IEP4 of the second air grid 70B may overlap each other at the intersections of the first and second inner center lines ICL1 and ICL2.

In example embodiments, the fifth inner extension portions IEP5 and the sixth inner extension portions IEP6 of the third air grid 70R may overlap each other at the intersections of the first and second inner center lines ICL1 and ICL2.

Each of the second inner extension portions IEP2 may have a first grid width GWg in the first direction D1. Each of the fourth inner extension portions IEP4 may have a second grid width GWb in the first direction D1. Each of the sixth inner extension portions IEP6 may have a third grid width GWr in the first direction D1. In example embodiments, the first grid width GWg may be greater than the second grid width GWb. In example embodiments, the first grid width GWg may be greater than the third grid width GWr.

Each of the first inner extension portions IEP1 may have a first grid width′ GWg′ in the second direction D2. Each of the third inner extension portions IEP3 may have a second grid width′ GWb′ in the second direction D2. Each of the fifth inner extension portions IEP5 may have a third grid width′ GWr′ in the second direction D2. In example embodiments, the first grid width′ GWg′ may be greater than the second grid width′ GWb′. In example embodiments, the first grid width′ GWg′ may be greater than the third grid width′ GWr′.

In example embodiments, the first grid width GWg, the second grid width GWb, and the third grid width GWr may be substantially the same as the first grid width′ GWg′, the second grid width′ GWb′, and the third grid width′ GWr′, respectively.

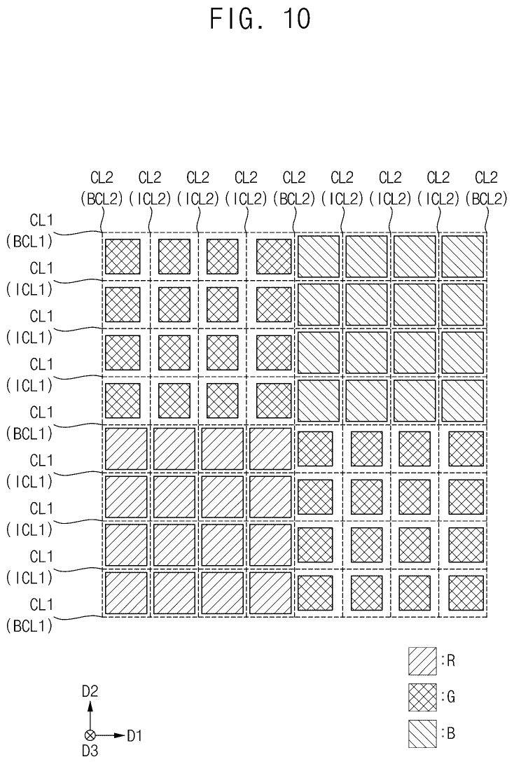

FIG. 10 is a cross-sectional view illustrating an image sensor according to example embodiments, corresponding to FIG. 9. The image sensor may be substantially the same or similar to those described with reference to FIG. 9 except that the first to third color filters G, B and R have a Tetra² layout, and thus, repeated descriptions of the same or similar elements may be omitted herein.

Referring to FIG. 10, each of the first color filter groups is shown to include sixteen of the first color filters G arranged in 4 rows and 4 columns, each of the second color filter groups is shown to include sixteen of the second color filters G arranged in 4 rows and 4 columns, and each of the third color filter groups is shown to include sixteen of the third color filters R arranged in 4 rows and 4 columns, such that the first to third color filters G, B and R have a Tetra² layout, but the concept of the present invention is not limited thereto. For example, the first to third color filters G, B and R may have other extended arrangement structures such as a Tetra-cell layout, a Nona-cell layout, etc.

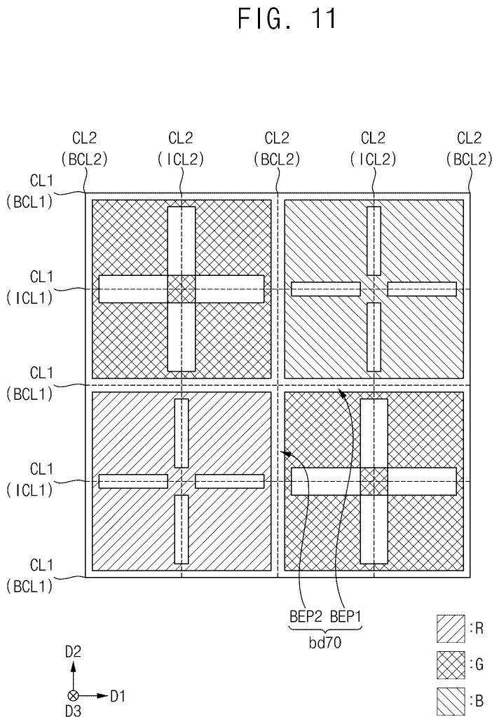

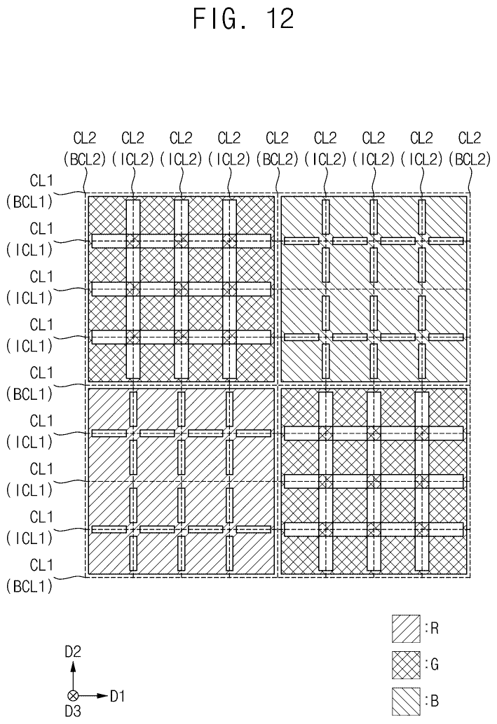

FIGS. 11 and 12 are cross-sectional views illustrating an image sensor according to example embodiments, corresponding to FIGS. 9 and 10, respectively. The image sensor may be substantially the same, or similar to those described with reference to FIGS. 9 and 10 and may differ primarily in the shape of the first to third air grids 70G, 70B and 70R, and thus, repeated description of elements described previously may be omitted herein.

In example embodiments, unlike the image sensor described with reference to FIGS. 9 and 10, the first inner extension portions IEP1 and the second inner extension portions IEP2 of the first air grid 70G may not overlap each other. For example, each of the first inner extension portions IEP1 of the first air grid 70G may be divided at the intersections of the first and second inner center lines ICL1 and ICL2 into a plurality of first inner extension sub portions spaced apart from each other in the first direction D1. For example, each of the second inner extension portions IEP2 of the first air grid 70G may be separated at the intersections of the first and second inner center lines ICL1 and ICL2 into a plurality of second inner extension sub portions spaced apart from each other in the second direction D2.

In example embodiments, unlike the image sensor explained with reference to FIGS. 9 and 10, the third inner extension portions IEP3 and the fourth inner extension portions IEP4 of the second air grid 70B may not overlap each other in the vertical direction. For example, each of the third inner extension portions IEP3 of the second air grid 70B may be separated at the intersections of the first and second inner center lines ICL1 and ICL2 into a plurality of third inner extension sub portions spaced apart from each other in the first direction D1. For example, each of the fourth inner extension portions IEP4 of the second air grid 70B may be separated at the intersections of the first and second inner center lines ICL1 and ICL2 into a plurality of fourth inner extension sub portions spaced apart from each other in the second direction D2.

In example embodiments, unlike the image sensor explained with reference to FIGS. 9 and 10, the fifth inner extension portions IEP5 and the sixth inner extension portions IEP6 of the third air grid 70R may not overlap each other. For example, each of the fifth inner extension portions IEP5 of the third air grid 70R may be separated at the intersections of the first and second inner center lines ICL1 and ICL2 into a plurality of fifth inner extension sub portions spaced apart from each other in the first direction D1. For example, each of the sixth inner extension portions IEP6 of the third air grid 70R may be separated at the intersections of the first and second inner center lines ICL1 and ICL2 into a plurality of sixth inner extension portions spaced apart from each other in the second direction D2.

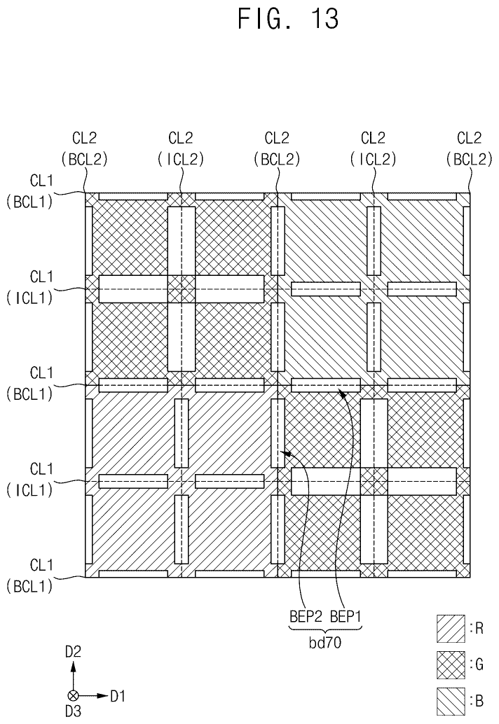

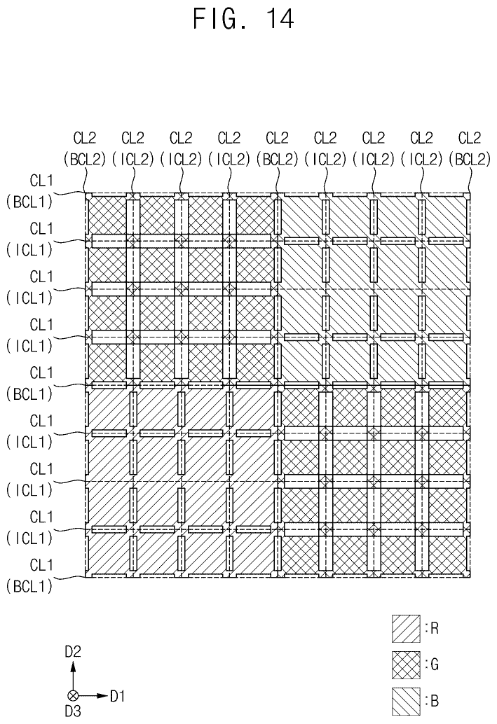

FIGS. 13 and 14 are cross-sectional views illustrating an image sensor according to example embodiments, corresponding to FIGS. 11 and 12, respectively. The image sensor may be substantially the same or similar to those described with reference to FIGS. 11 and 12 and may differ primarily in the shape of the boundary air grid bd70, and thus, repeated description of items described previously may be omitted herein.

In example embodiments, unlike the image sensor explained with reference to FIGS. 11 and 12, the first boundary extension portions BEP1 and the second boundary extension portions BEP2 of the boundary air grid bd70 may not overlap each other. For example, each of the first boundary extension portions BEP1 of the boundary air grid bd70 may be separated at the intersections of the first and second boundary center lines BCL1 and BCL2 and intersections of the first boundary center lines BCL1 and the second inner center lines ICL2 into a plurality of first boundary extension sub portions spaced apart from each other in the first direction D1. For example, each of the second boundary extension portions BEP2 of the boundary air grid bd70 may be separated at the intersections of the first and second boundary center lines BCL1 and BCL2 and the intersections of the first boundary center lines BCL1 and the second inner center lines ICL2 into a plurality of second boundary extension sub portions spaced apart from each other in the second direction D2.

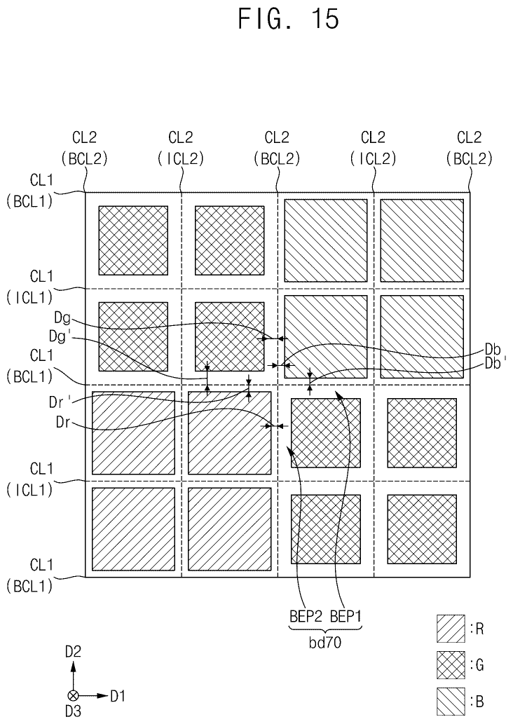

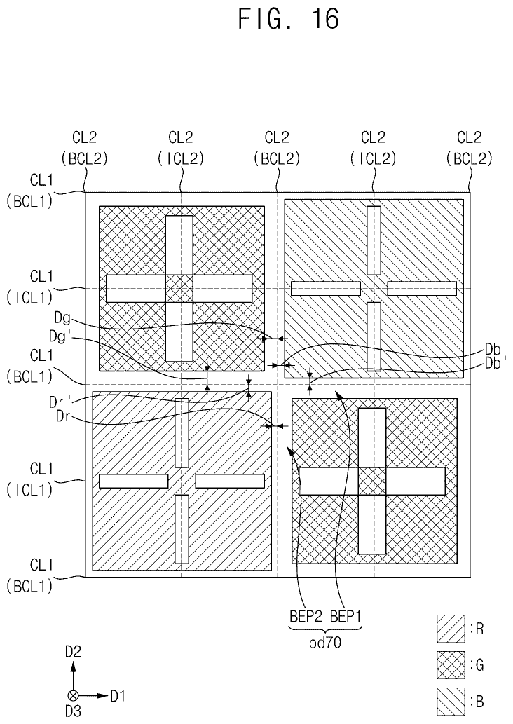

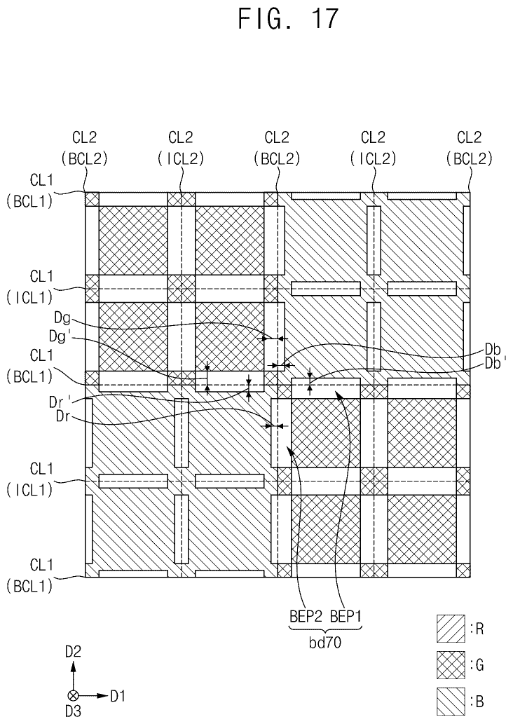

FIGS. 15 to 17 are cross-sectional views illustrating an image sensor according to example embodiments, corresponding to FIGS. 9, 11 and 13, respectively. The image sensor may be substantially the same or similar to those described with reference to FIGS. 9, 11 and 13 and may differ primarily in the distance between the first and second boundary center lines BCL1 and BCL2 and the color filters 60, and thus, repeated description of elements described previously may be omitted herein.

Referring to each of FIGS. 15 to 17, at the predetermined height H, the second boundary center line BCL2 and a sidewall facing the second center line CL2 in the first direction D1 of the first color filter G adjacent to the second boundary center line BCL2 in the first direction D1 may have a first distance Dg therebetween in the first direction D1. At the predetermined height H, the second boundary center line BCL2 and a sidewall facing the second center line CL2 in the first direction D1 of the second color filter B adjacent to the second boundary center line BCL2 in the first direction D1 may have a second distance Db therebetween in the first direction D1. At the predetermined height H, the second boundary center line BCL2 and a sidewall facing the second center line CL2 in the first direction D1 of the third color filter R adjacent to the second boundary center line BCL2 in the first direction D1 may have a third distance Dr therebetween in the first direction D1. In example embodiments, the first distance Dg may be greater than the second distance Db. In example embodiments, the first distance Dg may be greater than the third distance Dr.

At the predetermined height H, the first boundary center line BCL1 and a sidewall facing the first center line CL1 in the second direction D2 of the first color filter G adjacent to the first boundary center line BCL1 in the second direction D2 may have a first distance′ Dg′ therebetween in the second direction D2. At the predetermined height H, the first boundary center line BCL1 and a sidewall facing the first center line CL1 in the second direction D2 of the second color filter B adjacent to the first boundary center line BCL1 in the second direction D2 may have a second distance′ Db′ therebetween in the second direction D2. At the predetermined height H, the first boundary center lines BCL1 and a sidewall facing the first center line CL1 in the second direction D2 of the third color filters R adjacent to the first boundary center line BCL1 in the second direction D2 may have a third distance′ Dr′ therebetween in the second direction D2. In example embodiments, the first distance′ Dg′ may be greater than the second distance′ Db′. In example embodiments, the first distance′ Dg′ may be greater than the third distance′ Dr′.

In example embodiments, the first distance Dg, the second distance Db, and the third distance Dr may be substantially the same as the first distance′ Dg′, the second distance′ Db′, and the third distance′ Dr′, respectively.

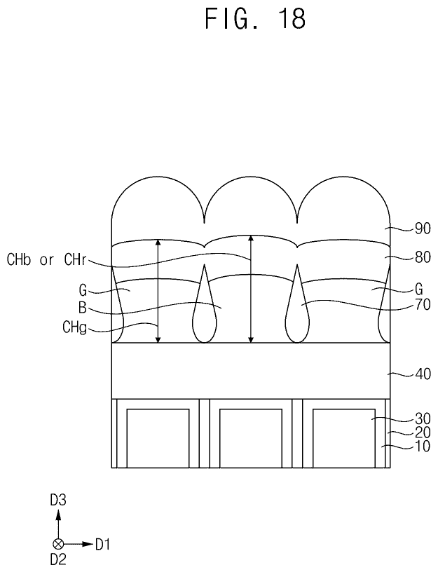

FIG. 18 is a cross-sectional view illustrating an image sensor according to example embodiments, corresponding to FIG. 2. The image sensor may be substantially the same or similar to those described with reference to FIGS. 1 and 2 and may differ primarily in the shape of the upper surface of the capping layer 80, and thus, repeated description of elements described previously may be omitted herein.

Referring to FIG. 18, a first portion of the capping layer 80 disposed on each of the first color filters G may have a first capping layer height CHg in the third direction D3, a second portion of the capping layer 80 disposed on each of the second color filters B may have a second capping layer height CHb in the third direction D3, and a third portion of the capping layer 80 disposed on each of the third color filters R may have a third capping layer height CHr in the third direction D3. In example embodiments, like the first filter height FHg and the second filter height FHb, which may correspond to the first capping layer height CHg and the second capping layer height CHb, respectively, the first capping layer height CHg may be smaller than the second capping layer height CHb. In example embodiments, like the first filter height FHg and the third filter height FHr, which may correspond to the first capping layer height CHg and the third capping layer height CHr, respectively, the first capping layer height CHg may be smaller than the third filter height CHr.

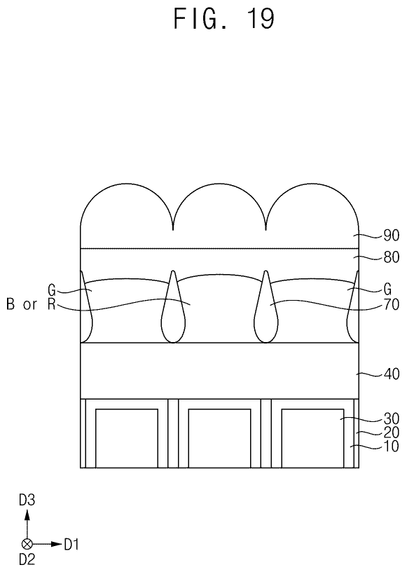

FIG. 19 is a cross-sectional view illustrating an image sensor according to example embodiments, corresponding to FIG. 2. The image sensor may be substantially the same or similar to those described with reference to FIGS. 1 and 2 and may differ primarily in the shape of the upper portion of the air grid 70, and thus, repeated explanations are omitted herein.

Referring to FIG. 19, the upper portion of the air grid 70 may have a rounded shape.

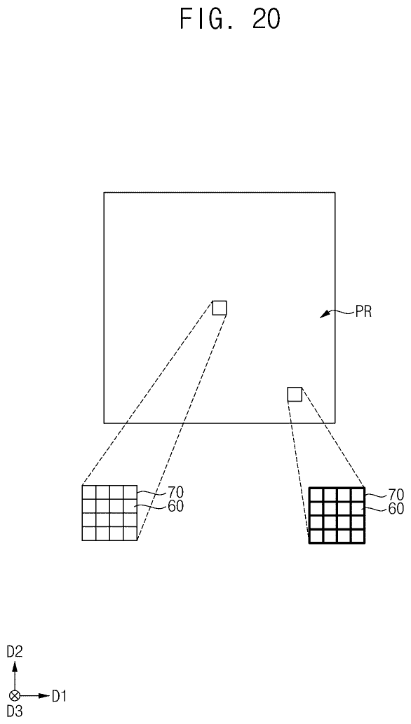

FIG. 20 is a plan view illustrating an image sensor according to example embodiments. The image sensor may be substantially the same or similar to those described with reference to FIGS. 1 and 2 and may differ primarily in the width of the air grid 70 in the horizontal direction according to the position within the pixel region. Repeated description of elements described previously may be omitted herein.

Referring to FIG. 20, the unit pixel regions may be spaced apart from each other along the first and second directions D1 and D2 within a pixel region PR.

The width in the second direction D2 of each of the first extension portions EP1 of the air grid 70 and the width in the first direction D1 of each of the second extension portions EP2 may increase in a direction extending from a central portion to an edge portion of the pixel region PR. For example, the first to third distances Dg, Db and Dr, the first to third distances′ Dg′, Db′ and Dr′, the fourth and fifth distances (as described in relation to FIG. 9), the first to third grid widths GWg, GWb and GWr, and the first to third grid widths′ GWg′, GWb′ and GWr′ may increase in a direction extending from the central portion to the edge portion of the pixel region PR. Accordingly, the image sensor may secure a uniform sensitivity regardless of the position of a light sensing element within the pixel region PR.

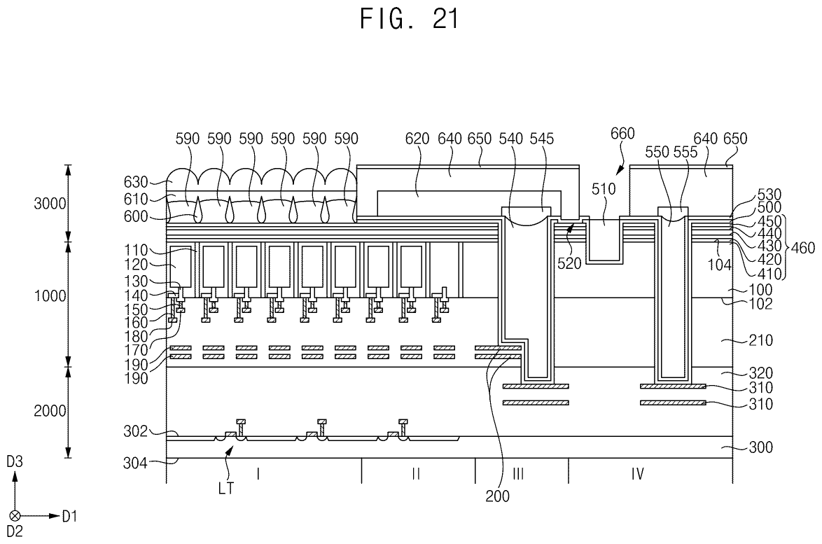

FIG. 21 is a cross-sectional view illustrating an image sensor in accordance with example embodiments. The image sensor may include the components illustrated with reference to FIGS. 1 and 2, such as, for example, color filters, air grid, capping layer, optical element, etc., and the description of the components described previously may be omitted herein.

In FIG. 21, two horizontal directions that intersect with one another and are parallel to a first surface 102 of a first substrate 100 may be referred to as first and second directions D1 and D2, respectively, and a direction perpendicular to the first surface 102 of the first substrate 100 may be referred to as a third direction D3. In example embodiments, the first and second directions D1 and D2 may be perpendicular to each other. Each of the first to third directions D1, D2, and D3 may also refer to a direction opposite to the direction shown in the drawings.

Referring to FIG. 21, the image sensor may include a logic circuit layer 2000, a photoelectric conversion circuit layer 1000, and a light transmission layer 3000 sequentially stacked in the third direction D3. Additionally, the image sensor may further include a pad 510, a first through via structure and a second through via structure.

The photoelectric conversion circuit layer 1000 may include first to fourth regions I, II, III and IV. In example embodiments, the first region I may have a shape of a square or a rectangle in a plan view, the second region II may surround the first region I, the fourth region IV may surround the second region II, and the third region III may be disposed in the fourth region IV, however, the inventive concept may not be limited thereto.

In example embodiments, the first region I may be an active pixel region in which active pixels are provided, the second region II may be an Optical Black (OB) region in which OB pixels are provided, the third region III may be an extension region in which the first through via structure is provided, and the fourth region IV may be a pad region in which the pad 510 is formed.

Hereinafter, for convenience of explanation, the portion of the logic circuit layer 2000 and the portion of the light transmission layer 3000 that overlap with the first region I of the photoelectric conversion circuit layer 1000 in the third direction D3 will also be referred to as the first region I, the portion of the logic circuit layer 2000 and the portion of the light transmission layer 3000 that overlap with the second region II of the photoelectric conversion circuit layer 1000 in the third direction D3 will also be referred to as the second region II, the portion of the logic circuit layer 2000 and the portion of the light transmission layer 3000 that overlap with the third region III of the photoelectric conversion circuit layer 1000 in the third direction D3 will also be referred to as the third region III, and the portion of the logic circuit layer 2000 and the portion of the light transmission layer 3000 that overlap with the fourth region IV of the photoelectric conversion circuit layer 1000 in the third direction D3 will also be referred to as the fourth region IV.

The photoelectric conversion circuit layer 1000 may include the first substrate 100, a pixel division pattern 110, light sensing elements 120, transfer transistors, pixel transistors PT, first and second vias 150 and 160, first to fourth wirings 170, 180, 190 and 200, and a first insulating interlayer 210.

The first substrate 100 may include the first and second surfaces 102 and 104 opposite to each other in the third direction D3. FIG. 21 shows that the first surface 102 is disposed under the second surface 104.

In example embodiments, p-type wells may be provided partially or entirely in the first substrate 100.

The pixel division pattern 110 may extend through the first substrate 100 in the third direction D3 in the first and second regions I and II, and in a plan view, may have a grid shape. The unit pixel regions defined by the pixel division pattern 110 may be spaced apart from each other along each of the first and second directions D1 and D2.

The light sensing elements 120 may be respectively disposed within the unit pixel regions defined by the pixel division pattern in the first and second regions I and II. The light sensing elements 120 may not be disposed in some of the unit pixel regions in the second region II.

In example embodiments, the light sensing elements 120 may be photodiodes PD. The light sensing elements 120 may be impurity regions doped with n-type impurities within the p-type wells in the first and second regions I and II, and accordingly, the light sensing elements 120 and the p-type wells may collectively form a PN junction diode. In an example embodiment, a region doped with a high concentration of p-type impurities may be additionally provided in a portion of the first substrate 100 adjacent to the pixel division pattern 110, and accordingly, a PN junction diode with improved performance may be provided.

The transfer transistors may include transfer gates (TG) 130 and floating diffusion regions (FD) 140 disposed below the first substrate 100 adjacent to the TGs 130. For example, the light sensing elements 120 may serve a source region of the TGs 130, and the FDs 140 may serve as a drain region of the TGs 130.

Each of TGs 130 may include a buried portion extending upward along the third direction D3 from the first surface 102 of the first substrate 100, and a protruding portion disposed below the buried portion and having a lower surface lower than the first surface 102 of the first substrate 100.

The FDs 140 may be provided in a portion of the first substrate 100 adjacent to the TGs 130. The FDs 140 may be, for example, regions doped with n-type impurities.

The pixel transistors PT may be disposed below the first substrate 100 adjacent to the first surface 102 of the first substrate 100. The pixel transistors PT may include, for example, a source follower transistor, a reset transistor, and a select transistor.

The first vias 150 may contact the TGs 130 above and may be connected to the first wirings 170 below. The second vias 160 may contact the FDs 140 above and may be connected to the second wirings 180 below.

Vias and wirings connected to the pixel transistors PT, for example, the source follower transistor, the reset transistor, and the select transistor, may be further provided within the first insulating interlayer 210 in the first and second regions I and II. In FIG. 21, the third and fourth wirings 190 and 200 is shown to be disposed at two levels in the third direction D3, respectively, but the concept of the present invention is not limited thereto, and the third and fourth wirings 190 and 200 may be respectively disposed in any number of multiple levels.

The first insulating interlayer 210 may include an oxide, for example, silicon oxide, or a low-k material having a lower dielectric constant than silicon oxide.

The light transmission layer 3000 may include a lower planarization layer 460, color filters 590, an air grid 600, a capping layer 610, a light blocking layer 620, an optical structure 630, an upper planarization layer 640, and a transparent electrode layer 650.

In an example embodiment, the lower planarization layer 460 may include first to fifth layers 410, 420, 430, 440 and 450 sequentially stacked along the third direction D3. For example, the first to fifth layers 410, 420, 430, 440 and 450 may include aluminum oxide, hafnium oxide, silicon oxide, silicon nitride, and hafnium oxide, respectively.

The color filters 590 may be disposed on the lower planarization layer 460 on the first region I.

The air grid 600 may be disposed on the lower planarization layer 460 and may have a grid shape in a plan view, corresponding to the pixel division pattern 110. The air grid 600 may include air.

The capping layer 610 may be disposed on the color filters 60 and may form an upper end of the air grid 600.

The light blocking layer 620 may be disposed on the lower planarization layer 460, the first through via structure and a first insulation pattern 530 in the second and third regions II and III of the first substrate 100. However, the light blocking layer 620 may not be provided on a portion of the first insulation pattern 530 on a fourth trench 520, which may be formed by partially removing a portion of a conductive pattern 500 on the lower planarization layer 460 at a boundary of the third and fourth regions III and IV to expose an upper surface of the lower planarization layer 460.

The optical structure 630 may be disposed on the capping layer 610 in the first region I.

The upper planarization layer 640 may be disposed on the light blocking layer 620, the first insulation pattern 530, and the second through via structure in the second to fourth regions II, III and IV, but may include a third opening 660 exposing an upper surface of the pad 510 in the fourth region IV.

In example embodiments, the optical structure 630 and the upper planarization layer 640 may include the same material, for example, a photoresist material with high transmittance.

The transparent electrode layer 650 may be disposed on the optical structure 630 and the upper planarization layer 640. The transparent electrode layer 650 may include, for example, ITO, IZO, ZnO, SnO₂, ATO (Antimony-doped Tin Oxide), AZO (Antimony-doped Zinc Oxide), GZO (Gallium-doped Zinc Oxide), TiO₂, FTO (Fluorine-doped Tin Oxide), etc.

The logic circuit layer 2000 may include a second substrate 300, a second insulating interlayer 320, logic transistors LT, and fifth wirings 310.

The second substrate 300 may include the third and fourth surfaces 302 and 304 opposite to each other in the third direction D3. FIG. 21 shows that the third surface 302 is disposed above the fourth surface 304.

The logic transistors LT may be disposed in an upper portion of the second substrate 300 adjacent to the third surface 302 of the second substrate 300.

Vias and wirings connected to the logic transistors LT may be provided within the second insulating interlayer 320. In FIG. 21, the fifth wirings 310 are shown to be disposed in two levels in the third direction D3, respectively, but the concept of the present invention is not limited thereto, and the fifth wirings 310 may be respectively disposed in any number of multiple levels.

The second insulating interlayer 320 may include an oxide, for example, silicon oxide, or a low-k material having a lower dielectric constant than silicon oxide.

The pad 510 may extend through the lower planarization layer 460 and an upper portion of the first substrate 100 in the fourth region IV. A sidewall and a lower surface of the pad 510 may be covered by the conductive pattern 500.

The pad 510 may be electrically connected with an outer wiring, and may be a path through which electrical signals may be input into the active pixels and/or the OB pixels, or electrical signals may be output from the active pixels and/or the OB pixels. The pad 510 may include a metal, e.g., aluminum.

The first through via structure may extend through the lower planarization layer 460, the first substrate 100, the first insulating interlayer 210, and an upper portion of the second insulating interlayer 320 in the third region III, and may commonly contact the fourth wiring 200 accommodated in the first insulating interlayer 210 and the fifth wiring 310 accommodated in the second insulating interlayer 320.

The first through via structure may include a first filling pattern 540 extending in the third direction D3 through the lower planarization layer 460, the first substrate 100, the first insulating interlayer 210 and the upper portion of the second insulating interlayer 320, the first insulation pattern 530 covering a lower surface and a sidewall of the first filling pattern 540, the conductive pattern 500 covering a lower surface and a sidewall of the first insulation pattern 530, and a first capping pattern 545 on an upper surface of the first filling pattern 540.

The second through via structure may extend through the lower planarization layer 460, the first substrate 100, the first insulating interlayer 210, and the upper portion of the second insulating interlayer 320 in the fourth region IV to contact the fifth wiring 310.

The second through via structure may include a second filling pattern 550 extending in the third direction D3 through the lower planarization layer 460, the first substrate 100, the first insulating interlayer 210 and an upper portion of the second insulating interlayer 320, the first insulation pattern 530 covering a lower surface and a sidewall of the second filling pattern 550, the conductive pattern 500 covering a lower surface and a sidewall of the first insulation pattern 530, and a second capping pattern 555 on an upper surface of the second filling pattern 550.

Each of the first and second filling patterns 540 and 550 may include, e.g., a low refractive index material (LRIM), and each of the first and second capping patterns 545 and 555 may include, e.g., a photoresist material.

A portion of the conductive pattern 500 included in the first through via structure may commonly contact the fourth and fifth wirings 137 and 310 so that the fourth and fifth wirings 137 and 310 may be electrically connected with each other, and a portion of the conductive pattern 500 included in the second through via structure may contact the fifth wiring 310 so as to be electrically connected thereto. The conductive pattern 500 may be included in the first and second through via structures, and may also be disposed on the lower planarization layer 460 in the second to fourth regions II, III and IV.

The conductive pattern 500 may include a metal, e.g., tungsten. In an example embodiment, a barrier pattern (not shown) including a metal nitride, e.g., titanium nitride may be further formed under the conductive pattern 500.

The first insulation pattern 530 may be included in the first and second through via structures, and may also be formed on a portion of the conductive pattern 500 on the lower planarization layer 460 in the second to fourth regions II, III and IV. As illustrated above, the first insulation pattern 530 may also be formed on the fourth trench 520 exposing the upper surface of the lower planarization layer 460 to partially contact the lower planarization layer 460. The first insulation pattern 530 may include an oxide, e.g., silicon oxide.

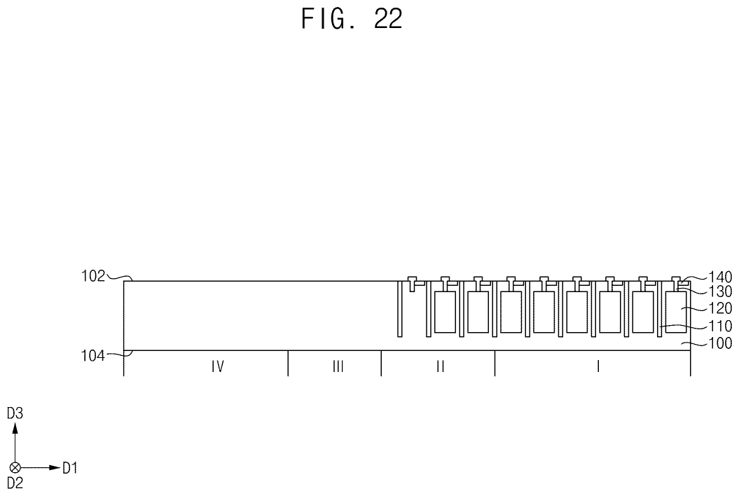

FIGS. 22 to 28 are cross-sectional views illustrating a method of manufacturing an image sensor in accordance with example embodiments.

Referring to FIG. 22, a pixel division pattern 110 and light sensing elements 120 may be formed in a first substrate 100 including first to fourth regions I, II, III and IV, and transfer gates (TG) 130 and floating diffusion regions (FD) 140 may be formed.

In example embodiments, p-type wells may be provided partially or entirely in the first substrate 100.

The pixel division pattern 110 may be formed to fill a first trench extending downward along the third direction D3 from the first surface 102 in the first and second regions I and II of the first substrate 100. In example embodiments, the pixel division pattern 110 may have a grid shape in a plan view.

In example embodiments, the light sensing elements 120 may be photodiodes PD. Accordingly, the light sensing elements 120 may be formed by doping n-type impurities into the P-type wells formed in the first and second regions I and II of the first substrate 100, and thus the light sensing elements 120 and the p-type wells may collectively form a PN junction diode. In an example embodiment, after forming the first trench for forming the pixel division pattern 110, a high concentration of p-type impurities may be additionally doped into a portion of the first substrate 100 adjacent to the first trench, thus forming a PN junction diode with improved performance.

However, although forming the light sensing elements 120 after forming the pixel division pattern 110 has been described so far, the concept of the present invention is not limited thereto, and the pixel division pattern 110 may be formed after forming the light sensing elements 120.

The TGs 130 may be formed by filling second trenches extending downward along the third direction D3 from the first surface 102 of the first substrate 100. In example embodiments, each of the TGs 130 may be formed to include a buried portion filling a second trench, and a protruding portion formed on the buried portion and having an upper surface higher than the first surface 102 of the first substrate 100.

Thereafter, the FDs 140 may be formed by doping, for example, n-type impurities into portions adjacent to the TGs 130.

The TGs 130 and the FDs 140 may collectively form transfer transistors.

Pixel transistors PT, for example, a source follower transistor, a reset transistor, and a select transistor, may be formed in an upper portion of the first substrate 100 adjacent to the first surface 102 of the first substrate 100.

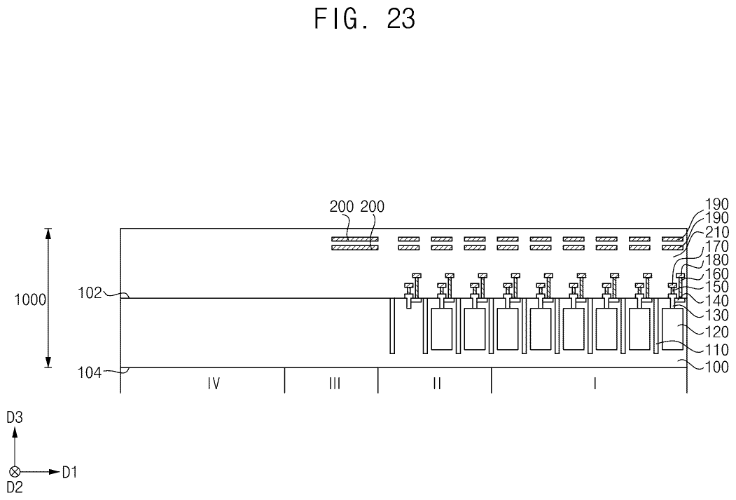

Referring to FIG. 23, first and second vias 150 and 160, first to fourth wirings 170, 180, 190 and 200, and a first insulating interlayer 210 accommodating the first and second vias 150 and 160 and the first to fourth wirings 170, 180, 190 and 200 may be formed on the first surface 102 of the first substrate 100.

The first vias 150 may contact the TGs 130 and also be connected to the first wirings 170 above. The second vias 160 may contact the FDs 140 and also be connected to the second wirings 180 above. The first to third wirings 170, 180 and 190 may be formed in the first and second regions I and II of the first substrate 100, and the fourth wirings 200 may be formed in the third region III of the first substrate 100.

Vias and wirings connected to the pixel transistors PT, for example, the source follower transistor, the reset transistor, and the select transistor, may be further formed on the first surface 102 of the first substrate 100. In example embodiments, the first and second vias 150 and 160 and the first to fourth wirings 170, 180, 190 and 200 may be formed by a dual damascene or single damascene process.

The first substrate 100, the pixel division pattern 110, the light sensing elements 120, the transfer transistors, the pixel transistors PT, the first and second vias 150 and 160, the first to fourth wirings 170, 180, 190 and 200, and the first insulating interlayer 210 may together form a photoelectric conversion circuit layer 1000.

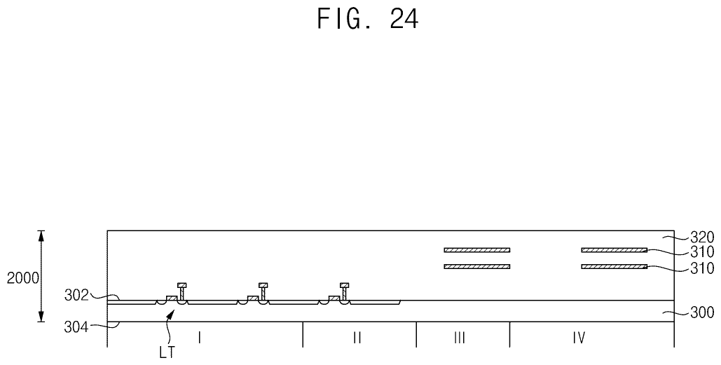

Referring to FIG. 24, logic transistors LT may be formed in an upper portion of a second substrate 300 adjacent to a third surface 302 of the second substrate 300 that has the third surface 302 and a fourth surface 304 opposing each other. Thereafter, fifth wirings 310 and a second insulating interlayer 320 accommodating the fifth wirings 310 may be formed on the third surface 302 of the second substrate 300.

In FIG. 24, the fifth wirings 310 are shown to be formed in two levels in the third direction D3, respectively, but the concept of the present invention is not limited thereto, and may be respectively formed in any number of multiple levels. The fifth wirings 310 may be electrically connected to each other through vias (not shown) that are disposed within the second insulating interlayer 320 between the fifth wirings 310. In example embodiments, the fifth wirings 310 and the vias may be formed by a dual damascene or single damascene process.

The second substrate 300, the second insulating interlayer 320, the logic transistors LT, and the fifth wirings 310 may collectively form a logic circuit layer 2000.

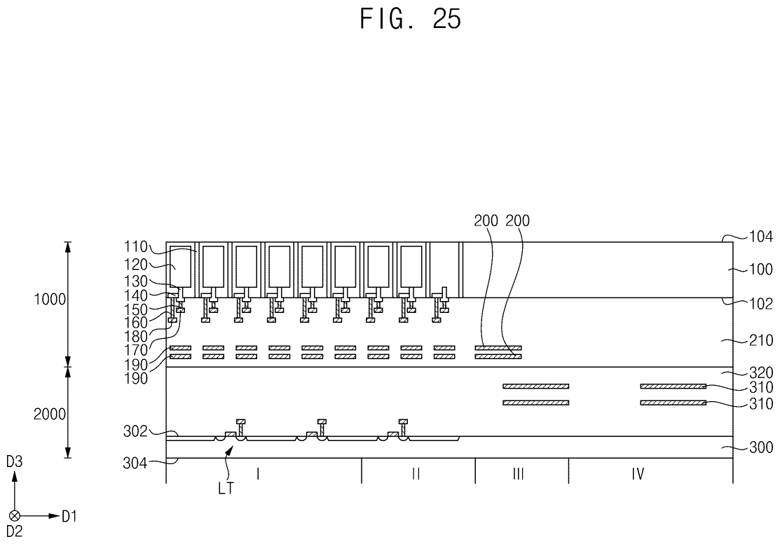

Referring to FIG. 25, the first insulating interlayer 210 on the first substrate 100 and the second insulating interlayer 320 on the second substrate 300 may be bonded with each other, and a portion of the first substrate 100 adjacent to the second surface 104 may be removed.

In example embodiments, the first and second insulating interlayers 210 and 320 may be bonded through a bonding layer (not shown). Alternatively, the first and second insulating interlayers 210 and 320 may be bonded without a separate bonding layer. After bonding the first and second insulating interlayers 210 and 320, the bonded structure may be flipped so that the second surface 104 of the first substrate 100 may face upward, and hereinafter, the bonded structure will be described with the second surface 104 of the first substrate 100 facing upward.

As the first and second substrates 100 and 300 are bonded with each other, the fifth wirings 310 on the second substrate 300 may be disposed in the third and fourth regions III and IV of the first substrate 100.

In example embodiments, the portion of the first substrate 100 adjacent to the second surface 104 may be removed by a polishing process, e.g., a grinding process. Thus, an upper surface of the pixel division pattern 110 may be exposed, and the pixel division pattern 110 may extend through the first substrate 100.

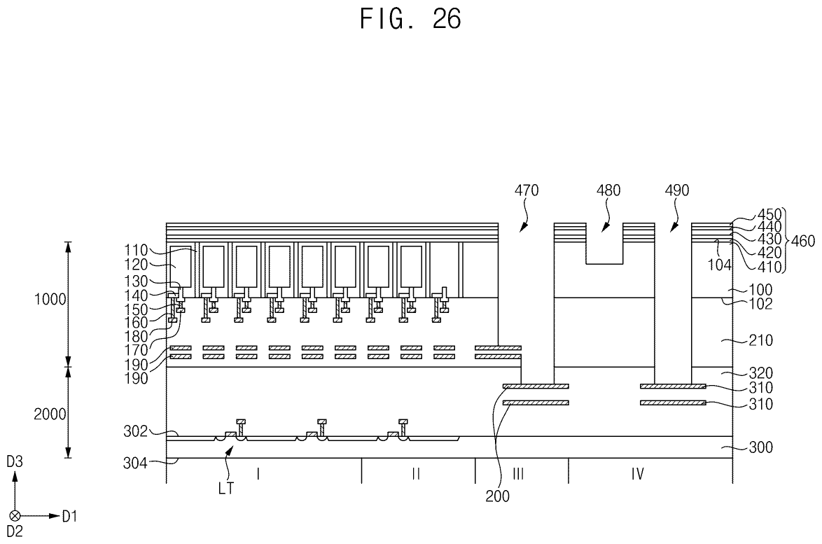

Referring to FIG. 26, a lower planarization layer 460 may be formed on the second surface 104 of the first substrate 100.

In an example embodiment, the lower planarization layer 460 may include first to fifth layers 410, 420, 430, 440 and 450 sequentially stacked in the third direction D3.

The lower planarization layer 460, the first substrate 100, the first insulating interlayer 210 and an upper portion of the second insulating interlayer 320 in the third and fourth regions III and IV of the first substrate 100 may be partially removed to form a first opening 470. The lower planarization layer 460 and an upper portion of the first substrate 100 in the fourth region IV may be removed to form a third trench 480. The lower planarization layer 460, the first insulating interlayer 210, and the upper portion of the second insulating interlayer 320 in the fourth region IV may be removed to form a second opening 490.

The first opening 470 may expose the fourth wiring 200 in the first insulating interlayer 210 and the fifth wiring 310 in the second insulating interlayer 320, and the second opening 490 may expose the fifth wiring 310 in the second insulating interlayer 320.

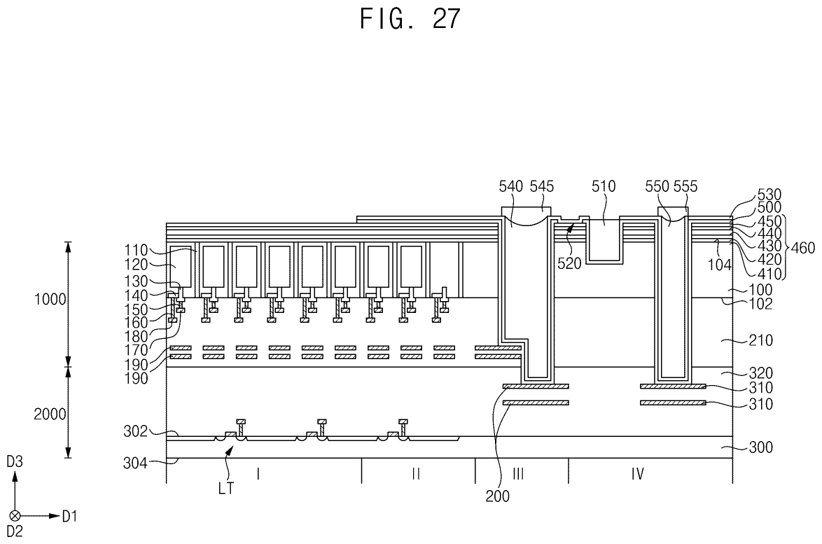

Referring to FIG. 27, a first conductive layer may be formed on bottoms and sidewalls of the first opening 470 and the third trench 480 and an upper surface of the lower planarization layer 460, a second conductive layer may be formed on the first conductive layer to fill the third trench 480, and an upper portion of the second conductive layer may be planarized until an upper surface of the first conductive layer is exposed. Thus, a pad 510 may be formed on the first conductive layer in the third trench 480 in the fourth region IV of the first substrate 100. The planarization process may be performed through, for example, a chemical mechanical polishing (CMP) process and/or an etch-back process.

Before forming the first conductive layer, a barrier layer may be further formed on the bottoms and sidewalls of the first opening 470 and the third trench 480 and the upper surface of the lower planarization layer 460.

The first conductive layer may be partially removed at a boundary area between the third and fourth regions III and IV of the first substrate 100 to form a fourth trench 520 exposing an upper surface of the lower planarization layer 460.

An insulation layer may be formed on upper surfaces of the first conductive layer and the pad 510 and a bottom and a sidewall of the fourth trench 520, a filling layer may be formed on the insulation layer to fill the first openings 470, and an upper portion of the filling layer may be planarized until an upper surface of the insulation layer is exposed.

An additional etching process may be performed on the filling layer so that a portion of the filling layer in the fourth trench 520 may be removed, and thus a first filling pattern 540 may be formed on the insulation layer in the first opening 470 in the third region III of the first substrate 100, and a second filling pattern 550 may be formed on the insulation layer in the second opening 490 in the fourth region IV of the first substrate 100.

A capping layer may be formed on the first and second filling patterns 540 and 550 and the insulation layer, and patterned to form first and second capping patterns 545 and 555 on the first and second filling patterns 540 and 550, respectively.

A portion of the insulation layer in the first region I of the first substrate 100 and a portion of the insulation layer on the pad 510 on the upper surface of the pad 510 may be removed to form a first insulation pattern 530, and a portion of the first conductive layer in the first region I of the first substrate 100 may be removed to form a conductive pattern 500. Thus, the upper surface of the lower planarization layer 460 in the first region I of the first substrate 100 may be exposed.

If the barrier layer is formed under the first conductive layer, the barrier layer may also be partially removed when the portion of the first conductive layer is removed to form a barrier pattern.

A portion of the conductive pattern 500 and the first insulation pattern 530 in the first opening 470, the first filling pattern 540 and the first capping pattern 545 in the third region III of the first substrate 100 may collectively form a first through via structure, and a portion of the conductive pattern 500 and the first insulation pattern 530 in the second opening 490, the second filling pattern 550 and the second capping pattern 555 in the fourth region IV of the first substrate 100 may collectively form a second through via structure.

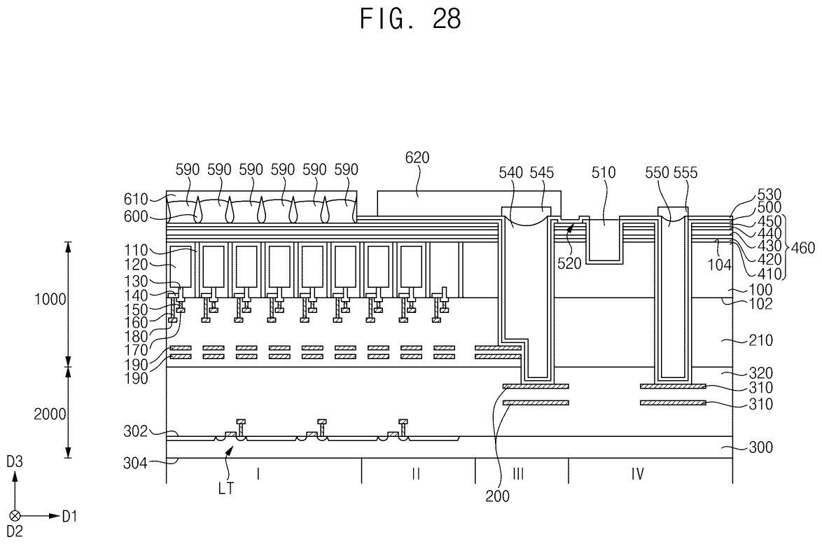

Referring to FIG. 28, color filters 590, an air grid 600, and a capping layer 610 may be formed by performing processes substantially the same or similar to those described with reference to FIGS. 3 to 6.

A light blocking layer 620 may be formed on the first insulation pattern 530 and the first capping pattern 545 in the second and third regions II and III of the first substrate 100.

Referring to FIG. 21 again, an upper planarization layer 640 may be formed on the capping layer 610, the light blocking layer 620, the first insulation pattern 530, the pad 510, and the second capping pattern 555 in the first to fourth regions I, II, III and IV of the first substrate 100, and a patterning process and a reflow process may be performed on the upper planarization layer 640 in the first region I of the first substrate 100 to form an optical structure 630.

A transparent electrode layer 650 may be formed on the optical structure 630 and the upper planarization layer 640, and a portion of the transparent electrode layer 650 overlapping the pad 510 in the fourth region IV of the first substrate 100 and a portion of the upper planarization layer 640 thereunder may be removed to form a third opening 660 exposing an upper surface of the pad 510.

The lower planarization layer 460, the color filters 590, the air grid 600, the capping layer 610, the light blocking layer 620, the optical structure 630, the upper planarization layer 640, and the transparent electrode layer 650 may collectively form a light transmission layer 3000.

An upper wiring (not shown) may be further formed to be electrically connected to the pad 510 so that the fabrication of the image sensor may be completed.

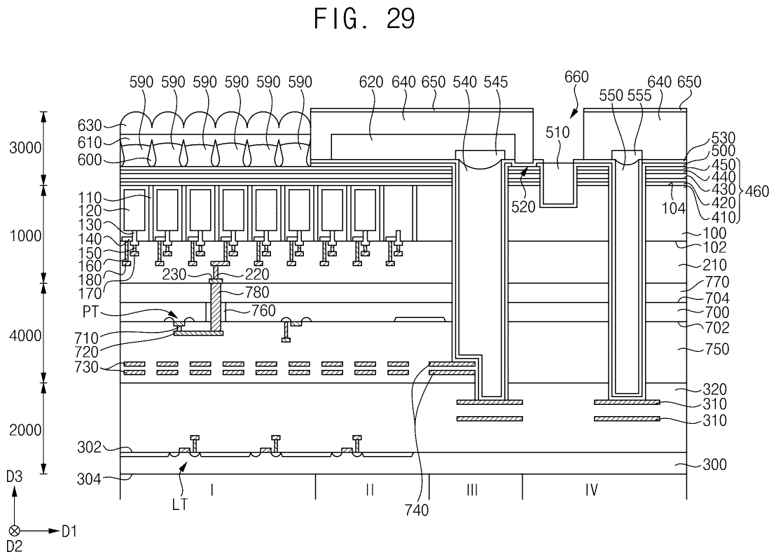

FIG. 29 is a cross-sectional view illustrating an image sensor in accordance with example embodiments. This image sensor may be substantially the same or similar to the image sensor described with reference to FIG. 21, and may differ primarily in the configuration of the photoelectric conversion circuit layer 1000 and the inclusion of a pixel circuit layer 4000, and thus repeated description of elements described previously may be omitted herein.

Referring to FIG. 29, the pixel circuit layer 4000 may be disposed between the logic circuit layer 2000 and the photoelectric conversion circuit layer 1000.

The pixel circuit layer 4000 may include a third substrate 700, pixel transistors PT, a third via 710, sixth to eighth wirings 720, 730 and 740, a third insulating interlayer 750, a second insulation pattern 760, a fourth insulating interlayer 770, and a third through via 780.

The third substrate 700 may include the fifth and sixth surfaces 702 and 704 opposite to each other in the third direction D3. FIG. 29 shows that the fifth surface 702 is disposed below the sixth surface 704.

The pixel transistors PT may be disposed in a lower portion of the third substrate 700 adjacent to the fifth surface 702 of the third substrate 700. The pixel transistors PT may include, for example, a source follower transistor, a reset transistor, and a select transistor.

The third insulating interlayer 750 may be disposed below the fifth surface 702 of the third substrate 700.

Vias and wirings connected to the pixel transistors PT may be accommodated in the third insulating interlayer 750. For example, the third via 710 may contact a gate of the pixel transistor PT above and may be connected to the sixth wiring 720 below. In FIG. 29, the seventh and eighth wirings 730 and 740 is shown to be disposed in two levels in the third direction D3, respectively, but the concept of the present invention is not limited thereto, the seventh and eighth wirings 730 and 740 may be respectively disposed in any number of multiple levels.

The fourth insulating interlayer 770 may be disposed on the sixth surface 704 of the third substrate 700.

The third through via 780 may extend through the fourth insulating interlayer 770 and the third substrate 700 in the third direction D3 and contact the upper surface of the sixth wiring 720. However, the third through via 780 may be insulated from the third substrate 700 by the second insulation pattern 760 that extends through the third substrate 700.

The photoelectric conversion circuit layer 1000 may further include a fourth via 220 and a ninth wiring 230. The fourth via 220 may contact the second wiring 180 above and may be connected to the ninth wiring 230 below. The ninth wiring 230 may be connected to the third through via 780 below.

The photoelectric conversion circuit layer 1000 may not include the pixel transistors PT and the third and fourth wirings 190 and 200.

The first through via structure may extend through the lower planarization layer 460, the first substrate 100, the first insulating interlayer 210, the fourth insulating interlayer 770, the third substrate 700, the third insulating interlayer 750, and the upper portion of the second insulating interlayer 320 in the third region III, and may commonly contact the eighth wiring 740 accommodated in the third insulating interlayer 750 and the fifth wiring 310 accommodated in the second insulating interlayer 320.

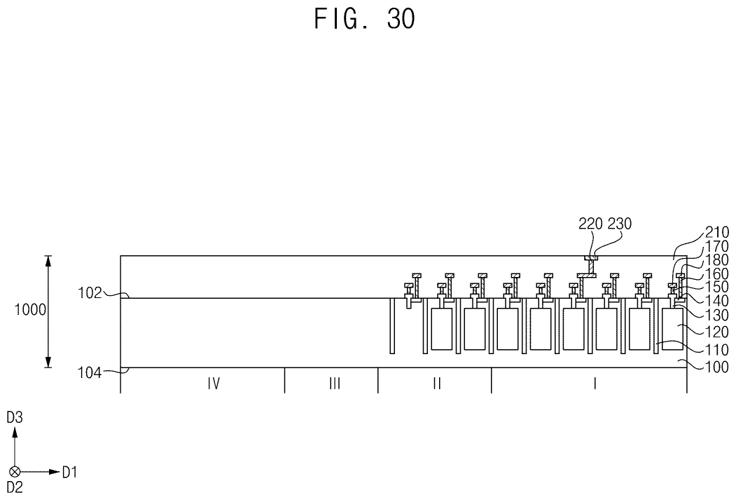

FIGS. 30 to 33 are cross-sectional views illustrating a method of manufacturing an image sensor in accordance with example embodiments. The method of manufacturing the image sensor includes processes substantially the same or similar to those described with reference to FIGS. 22 to 28 and FIG. 21, and thus repeated description of processes described previously may be omitted herein.

Referring to FIG. 30, processes substantially the same or similar to those explained with reference to FIGS. 22 and 23 may be performed.

However, the photoelectric conversion circuit layer 1000 may be formed to further include a fourth via 220 and a ninth wiring 230. The fourth via 220 may contact the second wiring 180 below and may be connected to the ninth wiring 230 above.

The photoelectric conversion circuit layer 1000 may be formed to not include the pixel transistors PT and the third and fourth wirings 190 and 200.

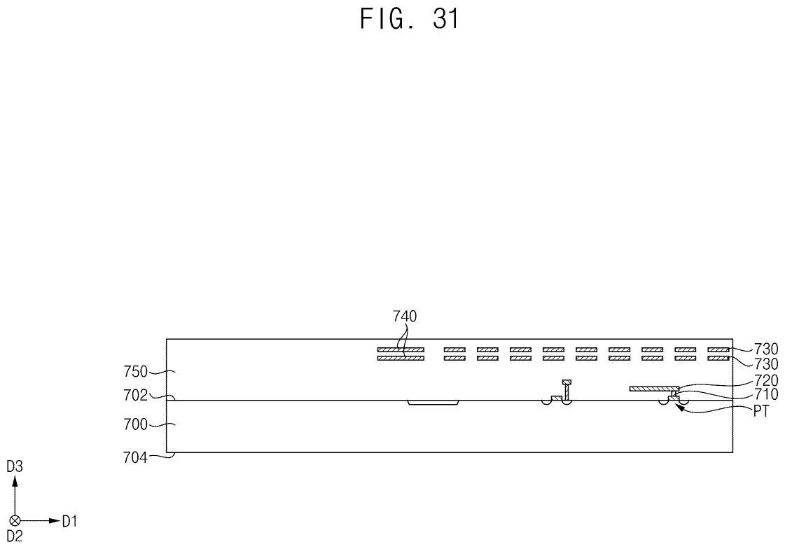

Referring to FIG. 31, pixel transistors PT may be formed in an upper portion of a third substrate 700 adjacent to a fifth surface 702 of the third substrate 700 that has the fifth surface 702 and a sixth surface 704 opposing each other. Thereafter, a third via 710, sixth to eighth wirings 720, 730 and 740, and a third insulating interlayer 750 accommodating the third via 710 and the sixth to eighth wirings 720, 730 and 740 may be formed on the fifth surface 702 of the third substrate 700.

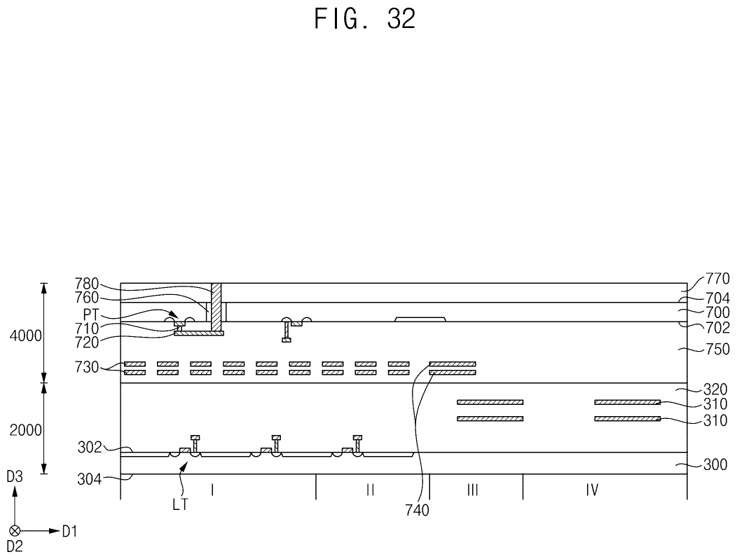

Referring to FIG. 32, the first insulating interlayer 210 on the first substrate 100 and the third insulating interlayer 750 on the third substrate 700 may be bonded with each other, and a portion of the third substrate 700 adjacent to the sixth surface 704 may be removed.

In example embodiments, the second and third insulating interlayers 320 and 750 may be bonded through a bonding layer (not shown). Alternatively, the second and third insulating interlayers 320 and 750 may be bonded without a separate bonding layer. After bonding the second and third insulating interlayers 320 and 750, the bonded structure may be flipped so that the sixth surface 704 of the third substrate 700 may face upward, and hereinafter, the bonded structure will be described with the sixth surface 704 of the third substrate 700 facing upward.

As the second and third substrates 300 and 700 are bonded with each other, the eighth wirings 740 on the third substrate 700 may be disposed in the third and fourth regions III and IV of the first substrate 100.

In example embodiments, the portion of the third substrate 700 adjacent to the sixth surface 704 may be removed by a polishing process, e.g., a grinding process. A second insulation pattern 760 may be formed to extend through a portion of the third substrate 700 that overlaps with the sixth wiring 720 in the third direction D3, and a fourth insulating interlayer 770 may be formed on the sixth surface 704 of the third substrate 700 and the second insulation pattern 760.

A third through via 780 may be formed to extend through the fourth insulating interlayer 770, the second insulation pattern 760, and an upper portion of the third insulating interlayer 750 and contact an upper surface of the sixth wiring 720.

The third substrate 700, the pixel transistors PT, the third via 710, the sixth to eighth wirings 720, 730 and 740, the third insulating interlayer 750, the second insulation pattern 760, the fourth insulating interlayer 770, and the third through via 780 may collectively form a pixel circuit layer 4000.

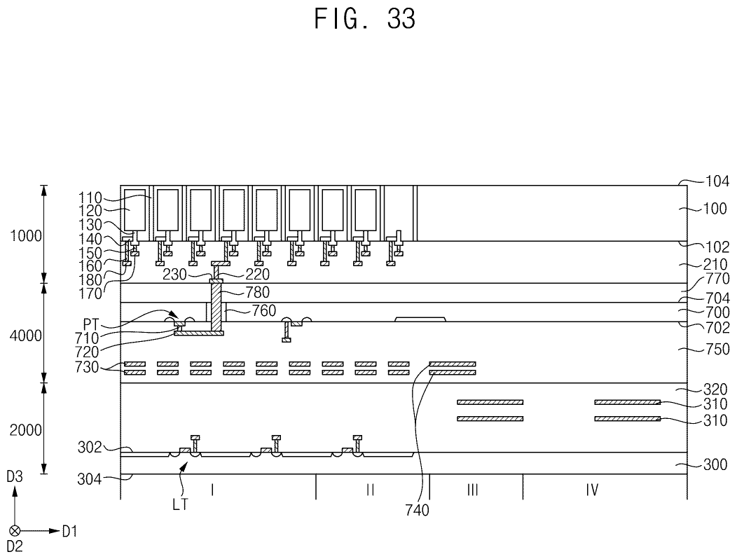

Referring to FIG. 33, the first insulating interlayer 210 on the first substrate 100 and the fourth insulating interlayer 770 and the third substrate 700 may be bonded with each other, and the portion of the first substrate 100 adjacent to the second surface 104 may be removed.

In example embodiments, the first and fourth insulating interlayer 210 and 770 may be bonded through a bonding layer (not shown). Alternatively, the first and fourth insulating interlayer 210 and 770 may be bonded without a separate bonding layer. After bonding the first and fourth insulating interlayer 210 and 770, the bonded structure may be flipped so that the second surface 104 of the first substrate 100 may face upward, and hereinafter, the bonded structure will be described with the second surface 104 of the first substrate 100 facing upward.

As the first and third substrates 100 and 700 are bonded with each other, the ninth wiring 230 on the first substrate 100 and the third through via 780 on the third substrate 700 may be connected to each other.

In example embodiments, the portion of the first substrate 100 adjacent to the second surface 104 may be removed by a polishing process, e.g., a grinding process. Thus, the upper surface of the pixel division pattern 110 may be exposed, and the pixel division pattern 110 may extend through the first substrate 100.

Referring again to FIG. 29, the manufacture of the image sensor may be completed by performing processes substantially the same or similar to those described with reference to FIGS. 26 to 28, and FIG. 21.

As described above, although the present invention has been described with reference to example embodiments, those skilled in the art will readily appreciate that many modifications are possible to the example embodiments without materially departing from the novel teachings and advantages of the present inventive concept.

What is claimed is:

1. An image sensor comprising:
a substrate;
a first photodiode and a second photodiode, the first and second photodiodes both disposed in the substrate and spaced apart from each other in a first direction parallel to an upper surface of the substrate;
a first color filter disposed on the first photodiode and a second color filter disposed on the second photodiode, the first and second color filters spaced apart from each other in the first direction; and
an optical structure disposed on the first and second color filters,
wherein, at a predetermined height, a first distance in the first direction from a center line between the first color filter and the second color filter to a sidewall of the first color filter facing the center line is greater than a second distance in the first direction from the sidewall of the second color filter facing the center line to the center line, and
wherein the center line extends in a second direction parallel to the upper surface of the substrate and crossing the first direction, and the center line is equidistant from a geometric center of the first color filter and a geometric center of the second color filter.

2. The image sensor of claim 1, wherein the first color filter is a green color filter, and the second color filter is a blue color filter or a red color filter.

3. The image sensor of claim 1, wherein the first color filter and the second color filter define an air grid between the first color filter and the second color filter that overlaps with the center line in a vertical direction perpendicular to the upper surface of the substrate.

4. The image sensor of claim 1, wherein the first color filter has a maximum first width in the first direction, the second color filter has a maximum second width in the first direction, and the maximum first width is smaller than the maximum second width.

5. The image sensor of claim 1, wherein the first color filter has a first height in a vertical direction perpendicular to the upper surface of the substrate, the second color filter has a second height in the vertical direction, and the first height is smaller than the second height.

6. The image sensor of claim 1, wherein the first color filter has a first volume, the second color filter has a second volume, and the first volume is smaller than the second volume.

7. An image sensor comprising:
a substrate; and
a first color filter group including first color filters among color filters that are disposed on the substrate and spaced apart from each other in a first direction and a second direction, the first direction parallel to an upper surface of the substrate and the second direction parallel to the upper surface of the substrate and crossing the first direction, the first color filters being adjacent to each other in the first and second directions; and
a second color filter group including second color filters among the color filters, the second color filters being adjacent to each other in the first and second directions, and the second color filter group being spaced apart from the first color filter group in the first direction;
wherein the first color filter group defines a first air grid including first inner extension portions and second inner extension portions, wherein the first inner extension portions extend in the first direction between the first color filters adjacent to each other in the second direction, the first inner extension portions are spaced apart from each other in the second direction, the second inner extension portions extend in the second direction between the first color filters adjacent to each other in the first direction, and the second inner extension portions are spaced apart from each other in the first direction,
wherein the second color filter group defines a second air grid including third inner extension portions and fourth inner extension portions, wherein the third inner extension portions extend in the first direction between the second color filters adjacent to each other in the second direction, the third inner extension portions are spaced apart from each other in the second direction, the fourth inner extension portions extend in the second direction between the second color filters adjacent to each other in the first direction, and the fourth inner extension portions are spaced apart from each other in the first direction, and
wherein, at a predetermined height, each of the first inner extension portions has a first width between opposing side surfaces of first color filters defining the first inner extension portion in the second direction, each of the third inner extension portions has a second width between opposing side surfaces of second color filters defining the third extension portions in the second direction, and the first width is greater than the second width.

8. The image sensor of claim 7, wherein the first color filters are green color filters, and the second color filters are blue color filters or red color filters.

9. The image sensor of claim 7, wherein each of the second inner extension portions has a third width in the first direction, each of the fourth inner extension portions has a fourth width in the first direction, and the third width is greater than the fourth width.

10. The image sensor of claim 7, wherein each of the first inner extension portions includes a plurality of first inner sub portions spaced apart from each other in the first direction, each of the second inner extension portions includes a plurality of second inner sub portions spaced apart from each other in the second direction, each of the third inner extension portions includes a plurality of third inner sub portions spaced apart from each other in the first direction, and each of the fourth inner extension portions includes a plurality of fourth inner sub portions spaced apart from each other in the second direction.

11. The image sensor of claim 7, wherein the first and second color filter groups define a boundary air grid extending in the second direction between the first and second color filter groups,
wherein, at a predetermined height, each of third color filters among the first color filters adjacent to the boundary air grid in the first direction is spaced apart from a center line by a first distance in the first direction, and, at the predetermined height, each of fourth color filters among the second color filters adjacent to the boundary air grid in the first direction is spaced apart from the center line by a second distance in the first direction,
wherein the center line is parallel to the upper surface of the substrate and extends in the second direction, and the center line is equidistant in the first direction from geometric centers of the third color filters and geometric centers of the fourth color filters, and
wherein the center line overlaps with the boundary air grid in a vertical direction perpendicular to the upper surface of the substrate.

12. The image sensor of claim 11, wherein the first distance and the second distance are equal to each other.

13. The image sensor of claim 11, wherein the first distance is greater than the second distance.

14. The image sensor of claim 11, wherein the boundary air grid includes a plurality of boundary air grid portions spaced apart from each other in the second direction.

15. The image sensor of claim 7, wherein each of the first color filters has a first volume, each of the second color filters has a second volume, and the first volume is smaller than the second volume.

16. An image sensor comprising:
a substrate;
photodiodes in the substrate and spaced apart from each other in a first direction and a second direction, the first direction parallel to an upper surface of the substrate and the second direction parallel to the upper surface of the substrate and crossing the first direction;
color filters spaced apart from each other in the first and second directions and respectively disposed on the photodiodes;
the color filters defining an air grid between adjacent color filters, the air grid including first extension portions and second extension portions, wherein the first extension portions extend in the first direction between the color filters adjacent to each other in the second direction, the first extension portions are spaced apart from each other in the second direction, the second extension portions extend in the second direction between the color filters adjacent to each other in the first direction, and the second extension portions are spaced apart from each other in the first direction;
a capping layer disposed on the color filters and over the air grid; and
an optical structure disposed on the capping layer,
wherein each of first color filters among the color filters has a first volume, each of second color filters among the color filters has a second volume, and the first volume is smaller than the second volume.

17. The image sensor of claim 16, wherein the first color filters are green color filters, and the second color filters are blue color filters or red color filters.

18. The image sensor of claim 16, wherein, at a predetermined height, each of the first color filters has a first width in the first direction, and, at the predetermined height, each of the second color filters has a second width in the first direction, and the first width is smaller than the second width.

19. The image sensor of claim 16, wherein each of the first color filters includes a first central portion and first corner portions, the first central portion having a rectangular shape in a plan view and having a first width at a predetermined height in the first direction, and the first corner portions respectively disposed at vertices of the first central portion,
wherein each of the second color filters includes a second central portion and second corner portions, the second central portion having a rectangular shape in a plan view and having a second width at the predetermined height in the first direction, and the second corner portions respectively disposed at vertices of the second central portion, and
wherein the first width is smaller than the second width.

20. The image sensor of claim 19, wherein each of the first color filters further includes first side protrusions on sidewalls in the first and second directions of the first central portion, and each of the second color filters further includes second side protrusions on sidewalls in the first and second directions of the second central portion.
